(19) United States
(12) Patent Application Publication
(10) Pub. No.: US 2007/0290271 A1
(43) Pub. Date: Dec. 20, 2007

(54) Semiconductor device and method of manufacturing the same

(75) Inventor: Yoshihiko Kusakabe, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 11/808,959

(22) Filed: Jun. 14, 2007

(30) Foreign Application Priority Data
Jun. 14, 2006 (JP) 2006-165042(P)

(51) Int. Cl. H01L 29/76

(52) U.S. Cl. 257/374

(57) ABSTRACT

The semiconductor device whose yield and reliability improved, and its manufacturing method are offered.

A resist layer is formed so that the silicon nitride film and filling insulating film in region A may be covered. Then, in order to adjust the height position of the upper surface of a filling insulating film, a plasma etch back or fluoric acid is performed. Thereby, the filling insulating film on the silicon nitride film in region B is removed. Therefore, the problem that the residue of a filling insulating film remains on the silicon nitride film in region B is solved.

### CROSS-REFERENCE TO RELATED APPLICATION

The present application claims priority from Japanese patent application No. 2006-165042 filed on Jun. 14, 2006, the content of which is hereby incorporated by reference into this application.

### FIELD OF THE INVENTION

The present invention relates to the semiconductor device which has Self-Aligned Shallow Trench Element Isolation (Self-Aligned Shallow Trench Isolation) (henceforth “SA-STI”) insulating part, and its manufacturing method.

### DESCRIPTION OF THE BACKGROUND ART

From the former, the method by which the polysilicon layer which forms a floating gate electrode, and an STI insulating part are formed in self align with one mask is used, for example in the manufacturing process of a flash memory. This method is called SA-STI. There is the following advantage in this SA-STI.

In the conventional manufacturing process of a flash memory, a tunnel insulating film is formed on a semiconductor substrate after formation of a separation insulating film. Therefore, the problem which is not avoided in the conventional forming step of a trench isolation insulating film is avoidable. The problem is a problem resulting from a tunnel insulating film falling into a trench at the end portion of an active region. In other words, the problem is a problem that thickness reduction (thinning) of the tunnel insulating film will be done at the end portion of an active region. Therefore, since the generation of the above-mentioned problem will be prevented when using SA-STI, the above-mentioned reliability of a tunnel insulating film improves. Especially this method is effective in the flash memory in which greater importance is attached to especially the reliability of a tunnel oxide film.

In the forming step of a SA-STI insulating film, a trench and a floating gate electrode layer are simultaneously formed in the same patterning step using one mask, for example. Therefore, an alignment error is reduced. Therefore, SA-STI is required, also in order to do microfabrication of the semiconductor device and to be integrated highly.

Next, an example of a manufacturing method of a semiconductor device in which a SA-STI insulating film is formed is explained. First, a tunnel insulating film is formed on a semiconductor substrate. Next, a first polysilicon film and a silicon nitride film are formed on a tunnel insulating film. Then, a silicon nitride film, the first polysilicon film which becomes a part of a floating gate electrode, a tunnel insulating film, and a semiconductor substrate are etched one by one using one mask. Thereby, a trench is formed. Next, a trench is filled up with a filling insulating film. This insulating film turns into an element isolation insulating film. Next, flattening of the filling insulating film is done by CMP (Chemical Mechanical Polishing) until the front surface of a silicon nitride film is exposed. Then, a silicon nitride film is removed.

Next, the second polysilicon film which becomes a part of a floating gate electrode is formed so that a first polysilicon film, and a filling insulating film may be covered. Then, the first and the second polysilicon film are removed partially and patterned. As a result, the forming step of SA-STI is completed.

In the usual semiconductor device, as well as the above-mentioned thing, when a gate insulating film is formed instead of a tunnel insulating film, according to the manufacturing method which forms SA-STI, the problem which cannot be avoided when a conventional trench isolation insulating film is formed can be avoided. Even if SA-STI is used for formation of insulating films other than a tunnel insulating film and a gate insulating film, the above-mentioned problem is avoidable similarly.

The improvement technology of above-mentioned SA-STI is disclosed by Japanese Unexamined Patent Publication No. 2000-315738, Japanese Unexamined Patent Publication No. 2002-110830, etc., for example.

In Japanese Unexamined Patent Publication No. 2000-315738, etching the top end of a separation insulating film, after a silicon nitride film is removed is disclosed. According to this, it is suppressed that the residue of silicon occurs when etching a gate electrode layer. As a result, the short generation between gate electrodes is prevented.

In Japanese Unexamined Patent Publication No. 2002-110830, the technology in which the side wall of the polysilicon film used as a gate electrode layer and the side wall of a silicon substrate are etched after etching for forming a trench is disclosed. According to this, it is suppressed that the residue of polysilicon occurs at the time of etching of a gate electrode layer. As a result, the short generation between gate electrode layers is prevented.

[Patent Reference 1] Japanese Unexamined Patent Publication No. 2000-315738

[Patent Reference 2] Japanese Unexamined Patent Publication No. 2002-110830

### SUMMARY OF THE INVENTION

The structure where at least two or more kinds of tunnel insulating films from which thickness differs were formed on the semiconductor substrate may be formed on a semiconductor substrate using above-mentioned conventional SA-STI. This structure has the first region where a thick insulating film is formed on a semiconductor substrate, and the second region where a thin insulating film is formed on a semiconductor substrate. The upper surface of the silicon nitride film in the second region is positioned lower than the upper surface of the silicon nitride film in the first region.

Therefore, when a filling insulating film is polished by CMP (Chemical Mechanical Polishing), in the first region, all the filling insulating films on a silicon nitride film will be removed, and will expose the upper surface of a silicon nitride film. However, in the second region, a filling insulating film remains on a silicon nitride film. The filling insulating film on the silicon nitride film in this second region may remain as an etch residue after the etching step of the filling insulating film performed next. The etch residue of the filling insulating film in this second region reduces the reliability and the yield of a semiconductor device.

The present invention is made in view of an above-mentioned problem. A purpose is to offer the semiconductor device whose yield and reliability improved, and its manufacturing method.

A semiconductor device of one aspect of this invention has a semiconductor substrate, a first insulating film formed over a main front surface in a first region of the semiconductor substrate, a second insulating film thinner than the first insulating film formed over a main front surface in a second region of the semiconductor substrate, and a first electric conduction film formed over the first and the second insulating film. This semiconductor device has a first trench which penetrates the first electric conduction film and the first insulating film, and results in the first region from a main front surface of the semiconductor substrate to a position of a predetermined depth, a first element isolation insulating part projected from an upper surface of the first electric conduction film while being embedded at the first trench, a second trench which penetrates the first electric conduction film and the second insulating film, and results in the second region from a main front surface of the semiconductor substrate to a position of a predetermined depth, and a second element isolation insulating part projected from an upper surface of the first electric conduction film while being embedded at the second trench. This semiconductor device has a second electric conduction film formed along those form over a front surface of a top end of the first element isolation insulating part, an upper surface of the first electric conduction film, and a front surface of a top end of the second element isolation insulating part. A thickness of the first electric conduction film is substantially constant in the first region and the second region. A position of an under surface of the first insulating film is lower than a position of an under surface of the second insulating film. A difference of a position of an upper surface of the first insulating film and a position of an upper surface of the second insulating film is smaller than a difference of a thickness of the first insulating film, and a thickness of the second insulating film.

According to the above-mentioned structure, the difference of the position of the upper surface of a first insulating film and the position of the upper surface of a second insulating film is smaller than the difference in the corresponding structure of the conventional semiconductor device in which the under surface of a second insulating film is the same as or positioned lower than that of the position of the under surface of a first insulating film. Therefore, the difference of the height of the first electric conduction film from the main front surface of the semiconductor substrate in a first region and the height of the first electric conduction film from the semiconductor substrate in a second region is small as compared with the corresponding structure of a conventional semiconductor device. Therefore, fear of disconnection of a first electric conduction film in the borderline between a first region and a second region and its neighborhood is small as compared with the corresponding structure of a conventional semiconductor device. Therefore, the yield and reliability of a semiconductor device improve.

A semiconductor device of another aspect of this invention has a semiconductor substrate, a first insulating film formed over a main front surface in a first region of the semiconductor substrate, a second insulating film thinner than the first insulating film formed over a main front surface in a second region of the semiconductor substrate, and a first electric conduction film formed over the first and the second insulating film. This semiconductor device has a first trench which penetrates the first electric conduction film and the first insulating film, and results in the first region from a main front surface of the semiconductor substrate to a position of a predetermined depth, a first element isolation insulating part projected from the first electric conduction film or an upper surface of the first electric conduction film while being embedded at the first trench, a second trench which penetrates the first electric conduction film and the second insulating film, and results in the second region from a main front surface of the semiconductor substrate to a position of a predetermined depth, and a second element isolation insulating part projected from a first electric conduction film or an upper surface of the first electric conduction film while being embedded at the second trench. This semiconductor device has a second electric conduction film formed along those form over a front surface of a top end of the first element isolation insulating part, an upper surface of the first electric conduction film, and a front surface of a top end of the second element isolation insulating part. As for this semiconductor device a difference of a distance from an upper surface of the first insulating film to an upper surface of a first element isolation insulating part and a distance from an upper surface of the second insulating film to an upper surface of the second element isolation insulating part is smaller than a difference of a distance between an upper surface of the first insulating film, and an upper surface of the second insulating film.

According to the above-mentioned structure, as compared with the length of the first element isolation insulating part which projects from the upper surface of the first electric conduction film in a first region, the length of the second element isolation insulating part which projects from the upper surface of the first electric conduction film in a second region does not become extremely large. Therefore, the degree of the waviness of the second electric conduction film in a second region becomes small. As a result, fear of disconnection of the second electric conduction film in a second region is reduced. Therefore, the yield and reliability of a semiconductor device improve.

A semiconductor device of a further aspect of this invention has a semiconductor substrate, a first insulating film formed over a main front surface in a first region of the semiconductor substrate, a second insulating film thinner than the first insulating film formed over a main front surface in a second region of the semiconductor substrate, and a first electric conduction film formed over the first insulating film and the second insulating film. This semiconductor device has a first trench which penetrates the first electric conduction film and the first insulating film, and results in the first region from a main front surface of the semiconductor substrate to a position of a predetermined depth, a first element isolation insulating part projected from an upper surface of a first insulating film or the first electric conduction film while being embedded at the first trench, a second trench which penetrates the first electric conduction film and the second insulating film, and results in the second region from a main front surface of the semiconductor substrate to a position of a predetermined depth, and a second element isolation insulating part projected from an upper surface of the first electric conduction film or a second insulating film while being embedded at the second trench. This semiconductor device has a second electric conduction film formed along those form over a front surface of a top end of the first element isolation insulating part, an upper surface of the first electric conduction film, and a front surface of a top end of the second element isolation insulating part. A difference of a distance from an upper surface of the first electric conduction film to an upper surface of the first element isolation insulating part in the first region and a distance from an upper surface of the first electric conduction film to an upper surface of the second element isolation insulating part in the second region is smaller than a distance between an upper surface of the first insulating film, and an upper surface of the second insulating film.

According to the above-mentioned structure, the length of the second element isolation insulating part which projects from the first electric conduction film in a second region, or the upper surface of a second insulating film does not become extremely large as compared with the length of the first element isolation insulating part which projects from the first electric conduction film in a first region, or the upper surface of a first insulating film. Therefore, the degree of the waviness of the second electric conduction film in a second region becomes small as compared with the corresponding structure of a conventional semiconductor device. As a result, fear of disconnection of the second electric conduction film in a second region is reduced. Therefore, the yield and reliability of a semiconductor device improve.

In a method of manufacturing a semiconductor device of one aspect of this invention, first a structure where a first insulating film is formed over a main front surface in a first region of a semiconductor substrate, and a second insulating film thinner than the first insulating film which has an under surface positioned over a main front surface in a second region of the semiconductor substrate more highly than an under surface of the first insulating film is formed is prepared. Next, a first electric conduction film whose thickness is substantially constant is formed over the first insulating film and the second insulating film. Afterward a stopper film is formed over the first electric conduction film. Next a first trench which penetrates the stopper film, the first electric conduction film, and the first insulating film, and is prolonged from a main front surface of the semiconductor substrate to a first position of a predetermined depth is formed in the first region. Simultaneously, a second trench which penetrates the stopper film, the first electric conduction film, and the second insulating film, and is prolonged from a main front surface of the semiconductor substrate to a second position of a predetermined depth is formed in the second region. Next, a third insulating film which covers the first electric conduction film is formed while embedding each of the first trench and the second trench. Afterward, upper surface of the stopper film is exposed by Chemical Mechanical Polishing of the third insulating film. Next, a top end of the third insulating film in the first trench and the second trench is etched by using the stopper film as a mask. Afterward, the stopper film is removed. Next, a second electric conduction film is formed so that a form of a front surface of a top end of the third insulating film in the first region, an upper surface of the first electric conduction film, and a front surface of a top end of the third insulating film in the second region may be met.

According to the above-mentioned process, a possibility that the residue of a stopper film may remain in a second region is reduced. Therefore, the yield and reliability of a semiconductor device improve.

In a method of manufacturing a semiconductor device of another aspect of this invention, first a first insulating film is formed over a main front surface of a semiconductor substrate. Next, in a second region, a first insulating film is removed and a semiconductor substrate is exposed so that the first insulating film in a first region of the first insulating films may remain. Afterward, a second insulating film is formed over a main front surface of the semiconductor substrate in the second region. Next, a first electric conduction film whose thickness is substantially constant is formed over the first insulating film and the second insulating film. Afterward, a stopper film is formed over the first electric conduction film, Next, a first trench which penetrates the stopper film, the first electric conduction film, and the first insulating film, and is prolonged from a main front surface of the semiconductor substrate to a first position of a predetermined depth is formed in the first region. Simultaneously, a second trench which penetrates the stopper film, the first electric conduction film, and the second insulating film, and is prolonged from a main front surface of the semiconductor substrate to a second position of a predetermined depth is formed in the second region. Next, a third insulating film which covers the first electric conduction film is formed while embedding the first trench and the second trench. Afterward, an upper surface of the stopper film in the first region is exposed by Chemical Mechanical Polishing of the third insulating film. Next, removing the third insulating film in the second region positioned above an upper surface of the stopper film is removed where the first region is masked. Afterward, the third insulating film in the first trench and the second trench is etched by using the stopper film as a mask. Next, the stopper film is removed. Afterward, a second electric conduction film is formed so that a form of a front surface of a top end of the third insulating film in the first region, an upper surface of the first electric conduction film, and a front surface of a top end of the third insulating film in the second region may be met.

According to the above-mentioned process, a possibility that the residue of a stopper film may remain in a second region is reduced. Therefore, the yield and reliability of a semiconductor device improve.

In a method of manufacturing a semiconductor device of a further aspect of this invention, first a first insulating film is formed over a main front surface of a semiconductor substrate. Next a first insulating film in a first region of the first insulating films remains, the semiconductor substrate in a second region exposes by removing a first insulating film in the second region. Afterward a second insulating film thinner than the first insulating film is formed over a main front surface of the semiconductor substrate in the second region. Next, a first electric conduction film whose thickness is substantially constant is formed over the first insulating film and the second insulating film. Afterward Chemical Mechanical Polishing of the first electric conduction film in the first region is done. Next, a stopper film is formed over the first electric conduction film; Afterward a first trench which penetrates the stopper film, the first electric conduction film, and the first insulating film, and is prolonged from a main front surface of the semiconductor substrate to a first position of a predetermined depth is formed in the first region. Simultaneously a second trench which penetrates the stopper film, the first electric conduction film, and the second insulating film, and is prolonged from a main front surface of the semiconductor substrate to a second position of a predetermined depth is formed in the second region. Next, a third insulating film which covers the first electric conduction film is formed while embedding the first trench and the second trench. Afterward, an upper surface of the stopper film is exposed by Chemical Mechanical Polishing of the third insulating film. Next, the third insulating film in the first trench and the second trench is etched by using the stopper film as a mask. Afterward, the stopper film is removed. Next, a second electric conduction film is formed so that a form of a front surface of a top end of the third insulating film in the first region, an upper surface of the first electric conduction film, and a front surface of a top end of the third insulating film in the second region may be met.

According to the above-mentioned process, a possibility that the residue of a stopper film may remain in a second region is reduced. Therefore, the yield and reliability of a semiconductor device improve.

According to the present invention, the reliability and the yield of a semiconductor device improve.

### BRIEF DESCRIPTION OF THE DRAWINGS

FIG. 1 is a drawing showing the structure of the semiconductor device of Embodiment 1;

FIGS. 2 to 18 are drawings for explaining the manufacturing method of the semiconductor device of Embodiment 1;

FIG. 19 is a drawing showing the structure of the semiconductor device of Embodiment 2;

FIGS. 20 to 33 are drawings for explaining the manufacturing method of the semiconductor device of Embodiment 2;

FIG. 34 is a drawing showing the structure of the semiconductor device of Embodiment 3;

FIGS. 35 to 47 are drawings for explaining the manufacturing method of the semiconductor device of Embodiment 3; and

FIGS. 48 to 59 are drawings for explaining the manufacturing method of the semiconductor device of a comparative example.

### DETAILED DESCRIPTION OF THE PREFERRED EMBODIMENTS

The inventors of the present application use the manufacturing method of the following semiconductor devices as secret technology. However, according to the method, the following problems occur. Hereafter, the problem of the manufacturing method of the semiconductor device as a comparative example of the present invention is explained.

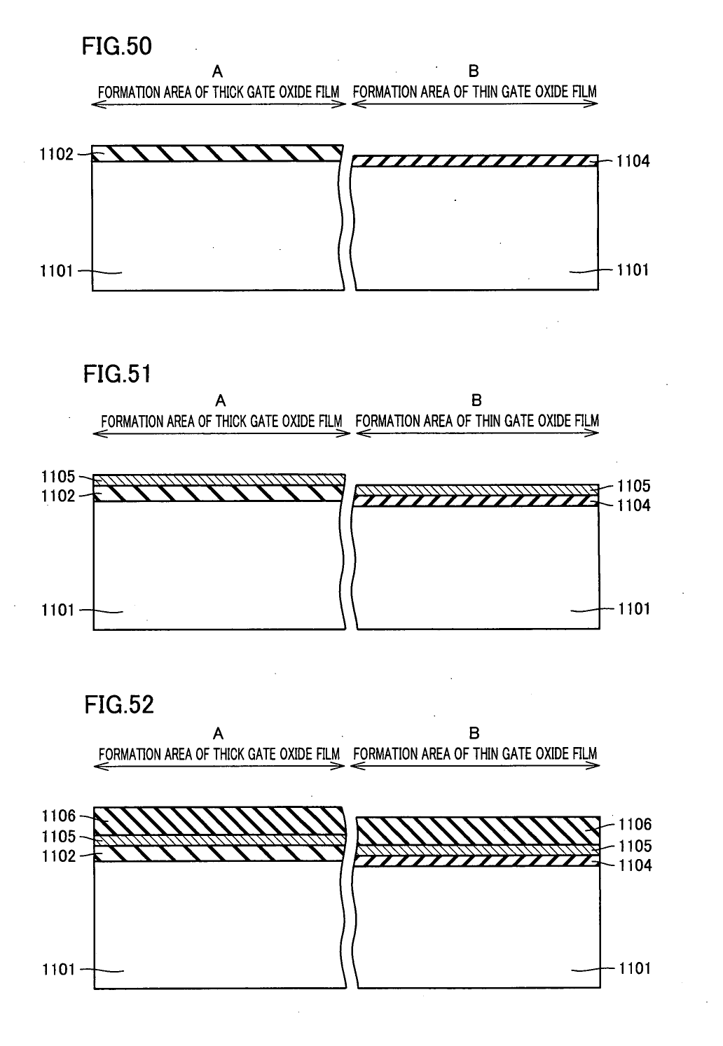

In the manufacturing method of the semiconductor device of a comparative example, first, as shown in FIG. 48, thick gate oxide film 1102 is formed on silicon substrate 1101 by the thermal oxidation of silicon substrate 1101. Next, resist layer 1103 is formed in region A. Next, etching of gate oxide film 1102 is performed by using resist layer 1103 as a mask. Thereby, as shown in FIG. 49, thick gate oxide film 1102 in region B is removed. As a result, the main front surface of silicon substrate 1101 is exposed. Then, by the thermal oxidation of silicon substrate 1101, as shown in FIG. 50, thin gate oxide film 1104 is formed on the main front surface of silicon substrate 1101 in region B.

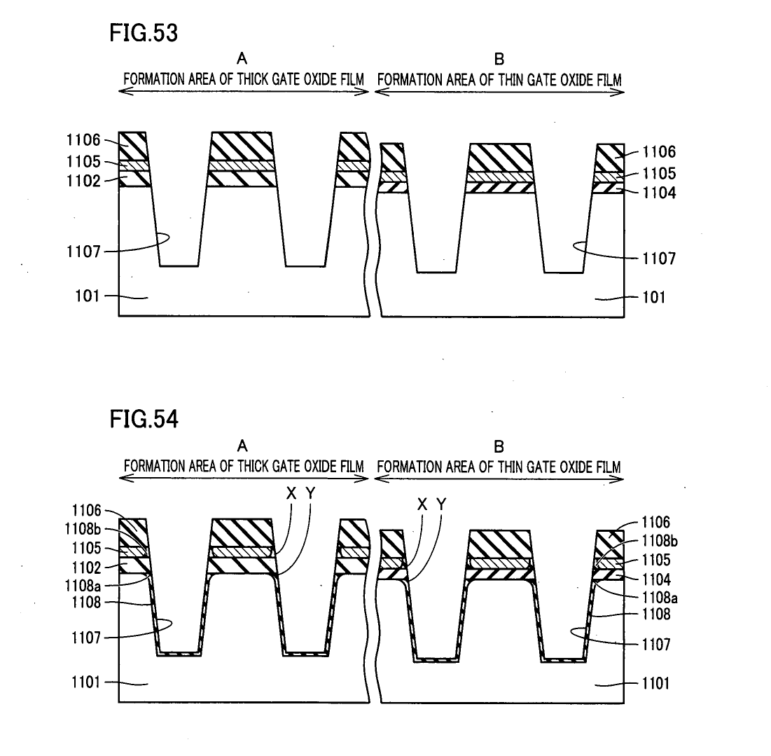

Next, as shown in FIG. 51, first polysilicon film 1105 is formed on thick gate oxide film 1102 and thin gate oxide film 1104. Next, as shown in FIG. 52, silicon nitride film 1106 is formed on first polysilicon film 1105. Next, one mask is used and silicon nitride film 1106, first polysilicon film 1105, gate oxide film 1102, and the portion of a main front surface to the predetermined depth of silicon substrate 1101 are etched. Thereby, trench 1107 is formed as shown in FIG. 53. At this time, the section form of first polysilicon film 1105 is almost trapezoidal shape with the bigger length of the lower side than the length of the upper side.

Then, as shown in FIG. 54, the internal surface of trench 1107 oxidizes and inner wall oxide film 1108 is formed. Thereby, bird's beak Y (1108a) is formed in the end portion of the active region located under gate oxide film 1104. Bird's beak X (1108b) is formed in the end portion of first polysilicon film 1105 located on gate oxide film 1104.

A corner part is rounded by bird's beaks X and Y Therefore, transistor characteristics are improved.

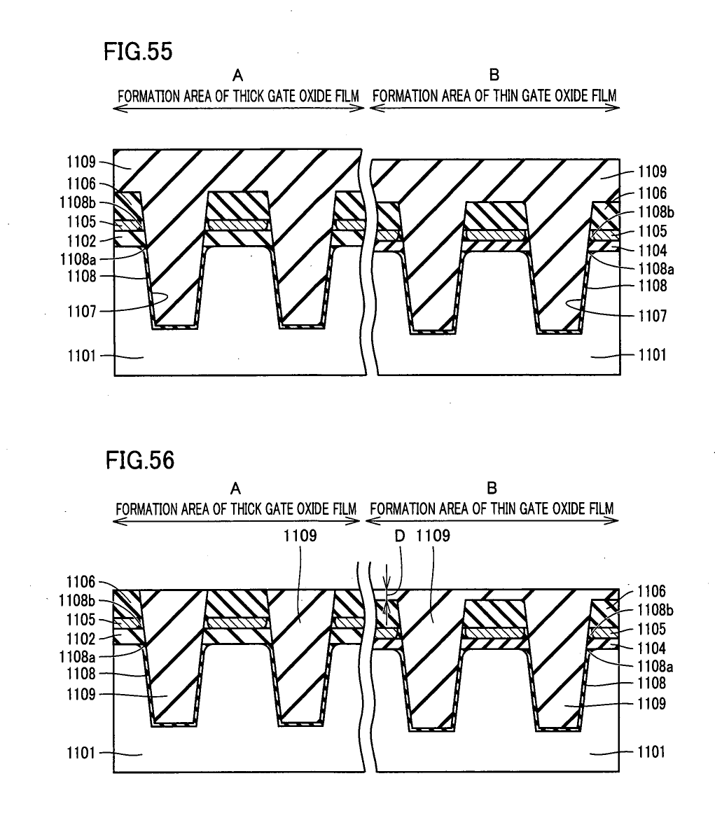

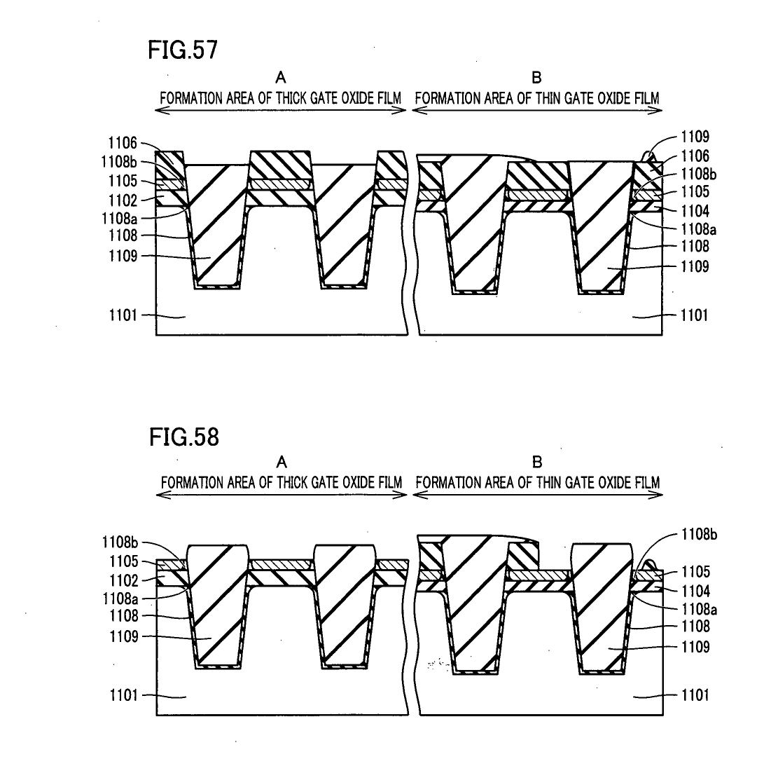

As shown in FIG. 55, trench 1107 is filled up with filling insulating film 1109. Filling insulating film 1109 is deposited by the CVD (Chemical Vapor Deposition) method. Next, flattening of the filling insulating film 1109 is done by CMP until the upper surface of silicon nitride film 1106 in region A is exposed, as shown in FIG. 56.

Next, as shown in FIG. 57, filling insulating film 1109 is etched by a plasma etch back or fluoric acid. At this time, the following problem occurs originating in the vertical interval of the upper surface of silicon nitride film 1106 in region A, and the upper surface of silicon nitride film 1106 in region B.

The upper surface of silicon nitride film 1106 in region A is positioned more highly than the upper surface of silicon nitride film 1106 in region B. Therefore, even after filling insulating film 1109 is fully etched, and the upper surface of silicon nitride film 1106 is exposed in region A, etching of filling insulating film 1109 may be continued to the degree in which the upper surface of silicon nitride film 1106 in region B exposes. In that case, in order to remove thoroughly filling insulating film 1109 in region B, after silicon nitride film 1106 is exposed in region A, etching of filling insulating film 1109 will be continued.

At this time, the upper surface of thick gate oxide film 1102 is positioned more highly than the upper surface of thin gate oxide film 1104. Therefore, the upper surface of filling insulating film 1109 in region A may be positioned by continued etching lower than the under surface of first polysilicon film 1105. In this case, thick gate oxide film 1102 will deteriorate by etching.

Therefore, etching quantity of a filling insulating film can seldom be enlarged. As a result, the etching quantity of filling insulating film 1109 in region B may not be enough. In this case, in region B, as shown in region B of FIG. 57, filling insulating film 1109 on silicon nitride film 1106 may not be removed thoroughly.

Then, as shown in FIG. 58, even if silicon nitride film 1106 is removed by etching, silicon nitride film 1106 of the remaining part lower part of filling insulating film 1109 in region B will remain. Therefore, silicon nitride film 1106 constitutes residue after the etching step of silicon nitride film 1106.

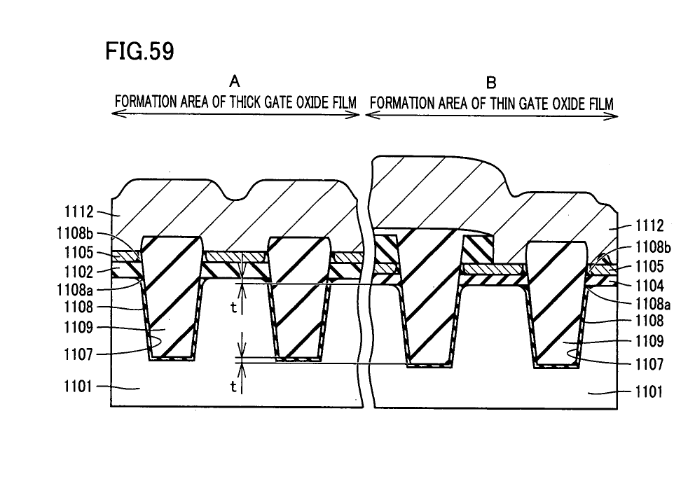

Next, as shown in FIG. 59, second polysilicon film 1112 is formed so that first polysilicon film 1105 and filling insulating film 1109 may be covered. Then, first polysilicon film 1105 and second polysilicon film 1112 are removed partially because of patterning, and the forming step of SA-STI is completed.

In the structure shown in FIG. 59, the device characteristics of the remaining part of silicon nitride film 1106 are not good. When a polysilicon film is removed, the silicon nitride film which remained will function as a mask. Therefore, the polysilicon film which should be removed will remain as a foreign substance. As a result, it may originate in the unnecessary polysilicon which remained and a short circuit may occur.

In the manufacturing method of the above-mentioned semiconductor device, the distance from first polysilicon film 1105 to the upper surface of filling insulating film (separation insulating film) 1109 in region B is larger than the distance from first polysilicon film 1105 to the upper surface of filling insulating film (separation insulating film) 1109 in region A. That is, in region B, since the level difference of a separation insulating film and a silicon substrate surface is large, it is easy to disconnect the wiring which straddles a level difference. In the photolithography process for patterning a wiring, a focal drift takes place easily. The width of filling insulating film (separation insulating film) 1109 becomes large as it goes upwards. Therefore, in region B, the portion projected from the upper surface of first polysilicon film 1105 of filling insulating film (separation insulating film) 1109 will function as eaves. Therefore, in the neighborhood, it is easy to generate the residue of silicon nitride film 1106 or polysilicon film 1105.

Hereafter, the semiconductor device of an embodiment of the invention and its manufacturing method with which the problem of the manufacturing method of the semiconductor device of the above-mentioned comparative example was canceled are explained, referring to a drawing.

### Embodiment 1

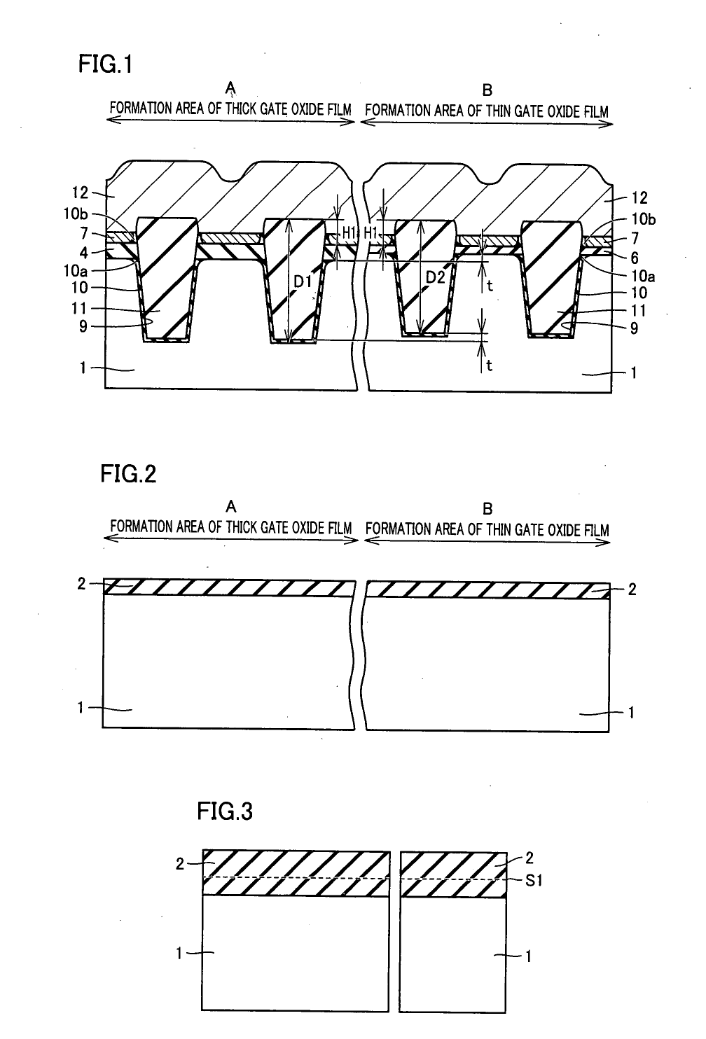

First, the semiconductor device of an embodiment of the invention and its manufacturing method are explained using FIG. 1-FIG. 18.

FIG. 1 is a drawing showing the structure of the semiconductor device of Embodiment 1. In the structure shown in FIG. 1, at least two kinds of insulating films from which thickness differs are formed on the active region of silicon substrate 1. The active region which has at least two kinds of insulating films is separated by at least one element isolation insulating film. Hereafter, the structure of the semiconductor device of this embodiment is explained concretely.

As shown in FIG. 1, the semiconductor device of this embodiment is provided with silicon substrate 1 as an example of the semiconductor substrate of the present invention. On the main front surface of silicon substrate 1 in region A, thick gate oxide film 4 as an example of the first insulating film of the present invention is formed. On the other hand, on the main front surface of silicon substrate 1 in region B, thin gate oxide film 6 as an example of the second insulating film of the present invention is formed. On each of thick gate oxide film 4 and thin gate oxide film 6, first polysilicon film 7 as a first electric conduction film of the present invention is formed. Since first polysilicon film 7 formed in region A and first polysilicon film 7 formed in region B are simultaneously formed in the same step, it has same and fixed thickness (about ±10%) within the limits of the variation generated when using the usual film formation technology.

In region A, first polysilicon film 7 and thick gate oxide film 4 are penetrated, and trench 9 which reaches the position of the predetermined depth from the main front surface of silicon substrate 1 is formed. Trench 9 in region A is equivalent to the first trench of the present invention. In region B, first polysilicon film 7 and thin gate oxide film 6 are penetrated, and trench 9 which reaches the position of the predetermined depth from the main front surface of silicon substrate 1 is formed. Trench 9 in region B is equivalent to the second trench of the present invention.

In this embodiment, inner wall silicon oxide film 10 as an example of the inner wall insulating film of the present invention is formed along the front surface of trench 9. Inner wall silicon oxide film 10 has bird's beak parts 10a and 10b. Bird's beak parts 10a and 10b are prolonged along the direction parallel to the main front surface of silicon substrate 1, respectively.

In the recess formed by inner wall silicon oxide film 10, insulating films, such as a -CVD oxide film, are embedded and filling insulating film (separation insulating film) 11 as an example of the element isolation insulating part of the present invention is formed. Filling insulating film 11 is prolonged from the upper surface of first polysilicon film 7 to the position of predetermined height. In accordance with the form of the upper surface of first polysilicon film 7, and the front surface of the top end of filling insulating film 11, second polysilicon film 12 as a second electric conduction film of the present invention is formed so that the upper surface of first polysilicon film 7 and the front surface of a top end of filling insulating film 11 may be covered.

Although the source/drain region is formed in silicon substrate 1 of thick gate oxide film 4 lower part and the source/drain region is formed also in silicon substrate 1 of thin gate oxide film 2 lower part, they are not illustrated for simplification of a drawing.

In the semiconductor device of this above-mentioned embodiment, before the step which forms two kinds of gate oxide films from which thickness differs on silicon substrate 1, the thermal oxidation process, and the removal process of a thermal oxidation film of silicon substrate 1 are performed so that the height of the main front surface of silicon substrate 1 may differ according to the thickness of each gate oxide film. That is, the height of the main front surface of silicon substrate 1 in region A differs from the height of the main front surface of silicon substrate 1 in region B so that the upper surface of thick gate oxide film 4 and the upper surface of thin gate oxide film 6 may be located in the same plane. The upper surface of thick gate oxide film 4 and the upper surface of thin gate oxide film 6 may not be into the same plane strictly, but what is necessary is to just be formed in the almost same height position within limits from which the effect of the present invention is acquired.

According to this, the degree of the waviness of second polysilicon film 12 in region B in which thin gate oxide film 6 is formed becomes small. As a result, disconnection of second polysilicon film 12 in region B, and the short circuit by the residue in the level difference part of the separation insulating part end when patterning second polysilicon film 12 and fear of the focal drift at the time of the photolithography process in subsequent steps become small.

When the difference of the position of the upper surface of thick gate oxide film 4 and the position of the upper surface of thin gate oxide film 6 is smaller than the difference of the thickness of thick gate oxide film 4, and the thickness of thin gate oxide film 6, as compared with the corresponding structure of the above-mentioned comparative example, fear of disconnection and a short circuit of second polysilicon film 12, and the generation of a focal drift in region B becomes small.

Distance H1 from the upper surface of thick gate oxide film 4 to the upper surface of filling insulating film 11 in region A and distance H1 from the upper surface of thin gate oxide film 6 to the upper surface of filling insulating film 11 in region B are the same. Distance H1 from the upper surface of thick gate oxide film 4 to the upper surface of filling insulating film 11 in region A and distance H1 from the upper surface of thin gate oxide film 6 to the upper surface of filling insulating film 11 in region B are not necessarily the same, but it is good when substantially the same within limits from which the effect of the present invention is acquired.

The bottom of trench 9 of region A is positioned lower than the bottom of trench 9 of region B. More concretely, difference t of the bottom of trench 9 of region A and the bottom of trench 9 of region B, and difference t of the under surface of thick gate oxide film 4 and the under surface of thin gate oxide film 6 are substantially the same. Therefore, distance D1 from the under surface of second polysilicon film 12 to the bottom of trench 9 in region A is larger than distance D2 from the under surface of second polysilicon film 12 to the bottom of trench 9 in region B. Therefore, the dielectric strength of filling insulating film 11 in region A is larger than the dielectric strength of filling insulating film 11 of region B.

Generally, voltage higher than the voltage applied to second polysilicon film 12 in region B in which thin gate oxide film 6 is formed is applied to second polysilicon film 12 in region A in which thick gate oxide film 4 is formed. That is, voltage higher than the transistor of region B is applied to the gate of the transistor of region A. Therefore, it is desirable for the semiconductor device as the last structure for the dielectric strength of filling insulating film 11 of region A to be larger than the dielectric strength of filling insulating film 11 of region B.

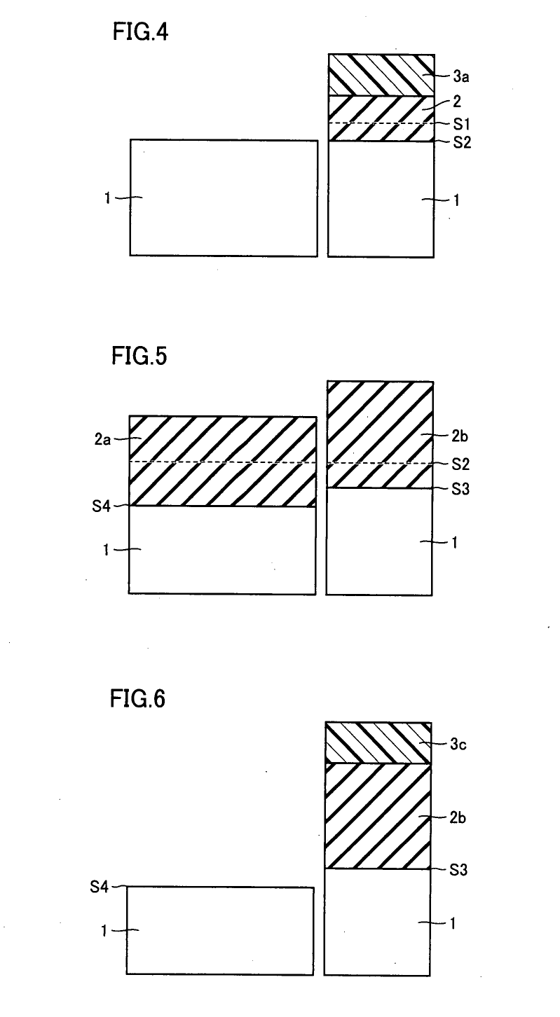

Next, with reference to FIG. 2-FIG. 18, the manufacturing method of the semiconductor device of this embodiment is explained. In the manufacturing method of the semiconductor device of Embodiment 1, first, in order to form the level difference of the main front surface of silicon substrate 1 as an example of a semiconductor substrate, thermal oxidation is performed. Thereby, as shown in FIG. 2, silicon oxide film 2 as an example of the first oxidation treatment insulating film of the present invention is formed on silicon substrate 1. The structure is expanded to FIG. 3 and shown. Next, as shown in FIG. 4, resist layer 3a is formed on silicon oxide film 2 in region B. Then, by using resist layer 3a as a mask, as shown in FIG. 4, silicon oxide film 2 in region A is removed by etching. Then, resist layer 3a is removed.

In FIG. 3 and FIG. 4, dotted line S1 shows the main front surface of the original silicon substrate 1. In FIG. 4, the main front surface of new silicon substrate 1 is shown by referential mark S2.

Next, thermal oxidation is performed again. Thereby, as shown in FIG. 5, silicon oxide film 2a as an example of the second oxidation treatment insulating film of the present invention is formed on silicon substrate 1 in region A. Simultaneously, silicon oxide film 2b as an example of the third oxidation treatment insulating film of the present invention which has bigger thickness than silicon oxide film 2 is formed on silicon substrate 1 in region B.

Next, resist layer 3c is formed on silicon oxide film 2b in region B. Then, silicon oxide film 2a in region A is removed by etching by using resist layer 3c as a mask. Thereby, the structure shown in FIG. 6 is acquired.

In FIG. 5 and FIG. 6, the main front surface of silicon substrate 1 shown in FIG. 4 is shown by dotted line S2. In FIG. 5 and FIG. 6, the main front surface of silicon substrate 1 in region B is shown by referential mark S3, and the main front surface of silicon substrate 1 in region A is shown by referential mark S4. Next, resist layer 3c is removed.

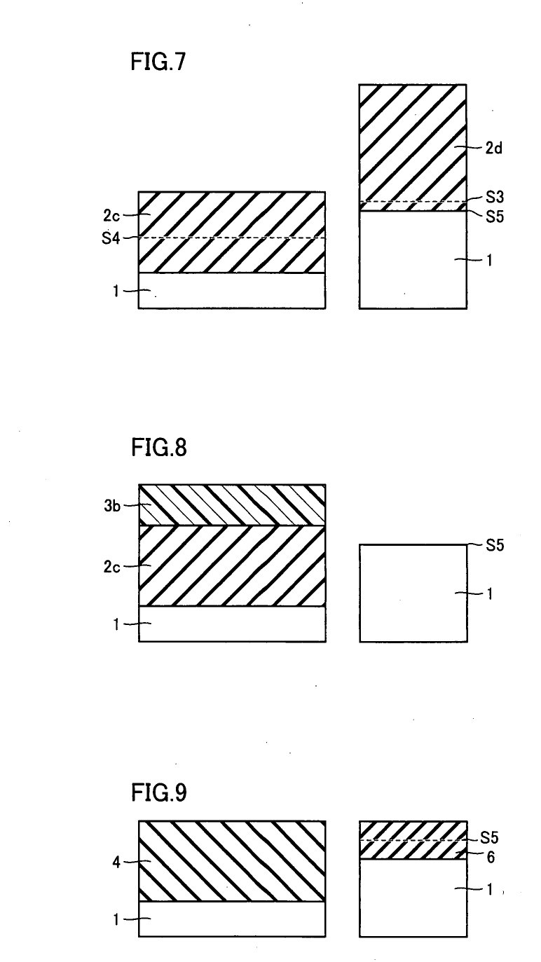

Then, as shown in FIG. 7, thermal oxidation is performed again. Thereby, on the main front surface of silicon substrate 1 in region A, silicon oxide film. 2c as an example of the fourth oxidation treatment insulating film of the present invention is formed. Simultaneously, on the main front surface of silicon substrate 1 in region B, silicon oxide film 2d as an example of the fifth oxidation treatment insulating film of the present invention which has bigger thickness than silicon oxide film 2b are formed.

Then, resist layer 3b is formed on silicon oxide film 2c in region A, and silicon oxide film 2d is removed by using resist layer 3b as a mask. Thereby, the structure shown in FIG. 8 is acquired. In region B of this structure, as shown by referential mark S5, the main front surface of new silicon substrate 1 is exposed.

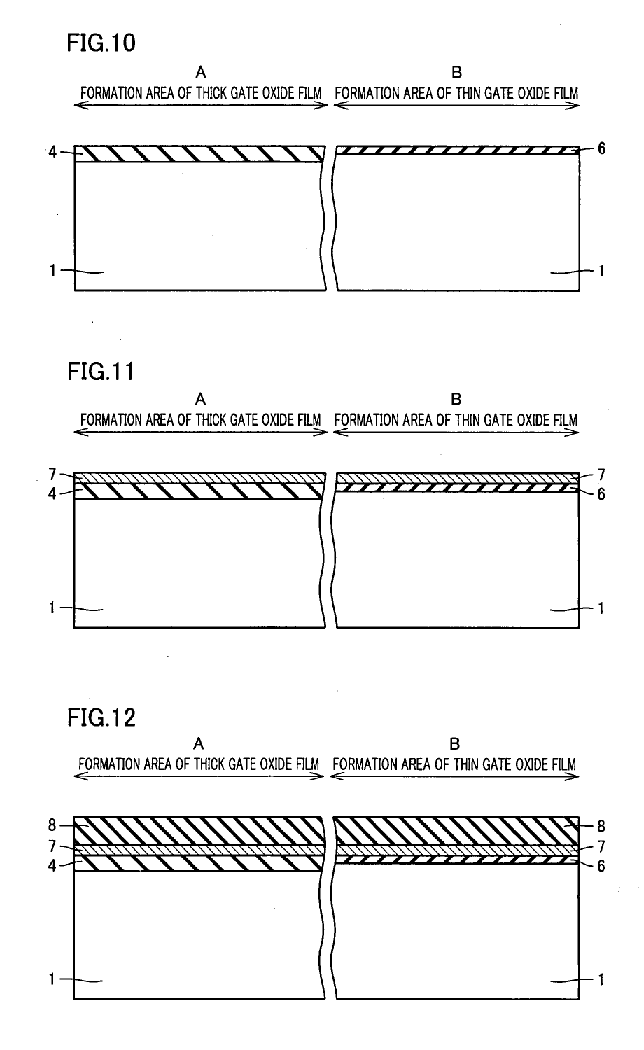

Next, resist layer 3b is removed. Then, thermal oxidation of the main front surface of silicon substrate 1 is done again. Thereby, as shown in FIG. 9, silicon oxide film 2c changes to thick gate oxide film 4 as an example of the first insulating film of the present invention on the main front surface of silicon substrate 1 in region A. Thin gate oxide film 6 as an example of the second insulating film of the present invention is formed on the main front surface of silicon substrate 1 in region B. In FIG. 9, the upper surface of thick gate oxide film 4 and the upper surface of a thin gate insulating film have the same height substantially. The entire structure is shown in FIG. 10.

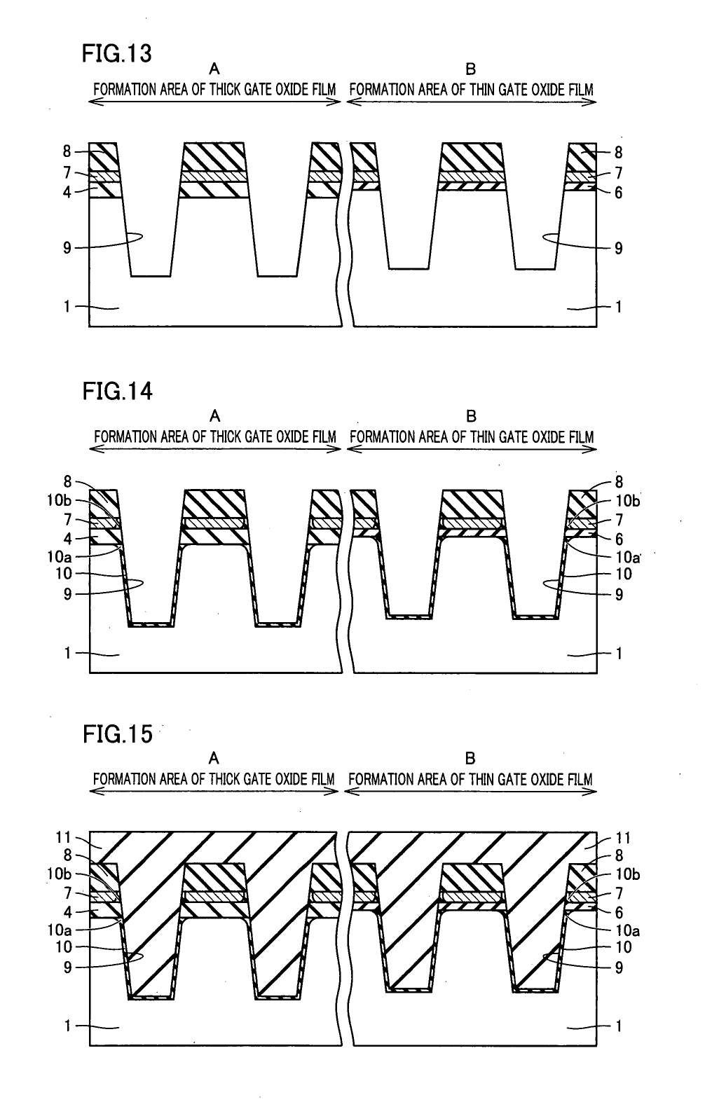

Then, as shown in FIG. 11, first polysilicon film 7 as an example of the first electric conduction film of the present invention is formed on thick gate oxide film 4 and thin gate oxide film 6. Next, as shown in FIG. 12, silicon nitride film 8 as an example of the stopper film of the present invention is formed on first polysilicon film 7. The stopper film should just be a film which consists of a different material from a gate oxide film and a filling insulating film. Then, as shown in FIG. 13, etching is performed using one mask. Thereby, in region A, silicon nitride film 8, first polysilicon film 7, thick gate oxide film 4, and silicon substrate 1 are etched. Simultaneously, in region B, silicon nitride film 8, first polysilicon film 7, thin gate oxide film 6, and silicon substrate 1 are etched. Thereby, in region A, trench 9 corresponding to the first trench of the present invention is formed, and trench 9 corresponding to the second trench of the present invention is formed in region B.

Next, as shown in FIG. 14, thermal oxidation of the inner surface of trench 9 is done, and inner wall silicon oxide film 10 as an example of the inner wall insulating film of the present invention is formed. At this time, bird's beak part 10a is formed in the position where the main front surface of silicon substrate 1 and the side wall of trench 9 cross. Thereby, the corner part at which the main front surface of silicon substrate 1 and trench 9 intersect is rounded.

Bird's beak part 10b is formed in first polysilicon film 7. At this time, the lower part of second polysilicon film 7 has the high concentration of an impurity (for example, P or B) as compared with the upper part of second polysilicon film 7. Therefore, the degree of oxidization of the lower part of second polysilicon film 7 is large as compared with the degree of oxidization of the upper part of second polysilicon film 7. As a result, the section form of first polysilicon film 7 changes from a trapezoid with the larger lower side than the upper side to the about inverted trapezoid form where the lower side is smaller than the upper side. The thickness of first polysilicon film 7 is 50 nm or less.

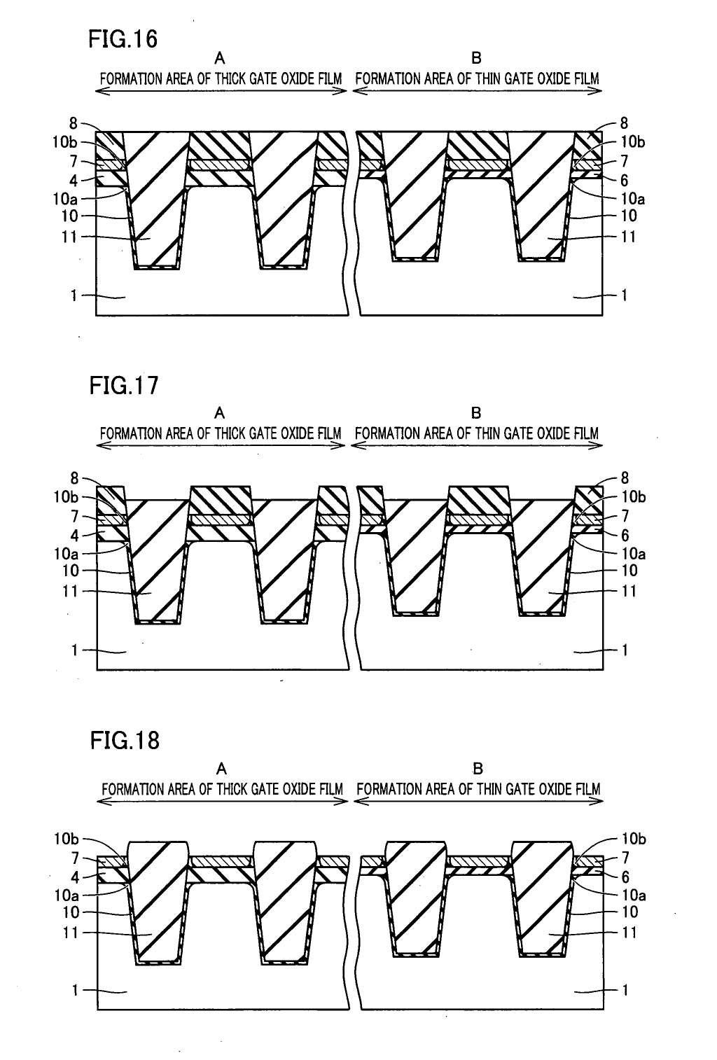

Then, as an example of a third insulating film, as shown in FIG. 15, while filling insulating films 11, such as a silicon oxide film is filled up in trench 9 by CVD (Chemical Vapor Deposition), they are formed of it so that silicon nitride film 8 may be covered. Next, as shown in FIG. 16, flattening of the filling insulating film 11 is done by an etch back or chemical mechanical polishing so that the upper surface of silicon nitride film 8 may be exposed. Here, silicon nitride film 8 functions as a stopper film of CMP (Chemical Mechanical Polishing). At this time, the height of the upper surface of filling insulating film 11 and the height of the upper surface of silicon nitride film 8 become the same also in any of regions A and B. Therefore, there is no possibility that filling insulating film 11 may remain on silicon nitride film 8 in region B, like the structure shown in above-mentioned FIG. 57 where a comparative example corresponds.

When the thickness of first polysilicon film 7 is 50 nm or less, even if the impurity is not introduced into first polysilicon film 7, section form will change from the form of the length of the lower side>length of the upper side to the form of the length of the upper side≧length of the lower side easily. It is because the oxidation seed (oxidizer) with which this oxidizes first polysilicon film 7 in a horizontal direction tends to diffuse the inside of a gate oxide film. It is preferred that the thickness of first polysilicon film 7 is 20 nm+10 nm, i.e., value of within the limits from 10 nm to 30 nm.

When first polysilicon film 7 is the laminated structure that impurity concentration becomes high as it goes to a lower part, it will change from the structure of providing the conditions of the length of the lower side>length of the upper side to the structure of providing the conditions of the length of the upper side≧length of the lower side, easily. Generally filling insulating film 11 originates in width having spread as it goes to the upper part, and it is easy to generate the etch residue of first polysilicon film 7 adhering to the side surface of filling insulating film 11. However, according to the above-mentioned structure, when first polysilicon film 7 is etched, the generation of the etch residue adhering to the side surface of filling insulating film 11 is suppressed. Even if the upper part of first polysilicon film 7 consists of non doped polysilicon and the lower part of first polysilicon film 7 consists of doped polysilicon, it becomes easy to change to the structure of the length of the upper side≧length of the lower side from the structure of the length of the lower side>length of the upper side.

Next, as shown in FIG. 17, in order to adjust the height of the upper surface of filling insulating film 11, the plasma etch back of the filling insulating film 11 (CVD oxide film) is done, or it etches using fluoric acid. At this time, silicon nitride film 8 functions as a stopper film. The height of the upper surface of filling insulating film 11 in region A and the height of the upper surface of filling insulating film 11 in region B become the same substantially after this etching. Then, as shown in FIG. 18, silicon nitride film 8 as a stopper film is removed by heat phosphoric acid. Thereby, the width of the portion which projects above first polysilicon film 7 of filling insulating film 11 becomes narrow.

Next, so that the form of the upper surface of first polysilicon film 7 and the front surface of the top end of filling insulating film 11 may be met as shown in FIG. 1, second polysilicon film 12 which forms the upper part of a gate electrode is formed on the upper surface of first polysilicon film 7, and the front surface of the top end of filling insulating film 11. Second polysilicon film 12 is an example of the second electric conduction film of the present invention. Then, first polysilicon film 7 and second polysilicon film 12 are removed partially because of patterning. Thereby, the gate electrode layer which consists of first polysilicon film 7 and second polysilicon film 12 is formed.

In the semiconductor device of this embodiment, an electrically conductive impurity, for example, phosphorus (P), is introduced into second polysilicon film 12. The doped amorphous silicon by which phosphorus (P) was doped (in-situ) in polysilicon may be used instead of second polysilicon film 12. After a non-doped amorphous silicon film or a polysilicon film is formed, phosphorus (P) may be doped by those films with ion implantation. As for the concentration of phosphorus (P), in this embodiment, it is desirable that it is about 1.0E²⁰ atms/cm³-1.0E²¹ atms/cm³.

According to the manufacturing method of the semiconductor device of this embodiment, the height of the upper surface of thin gate oxide film 6 and the height of the upper surface of thick gate oxide film 4 become the same substantially. Therefore, second polysilicon film 12, disconnecting originating in the level difference in the borderline between region A and region B, or short-circuiting with other wirings is prevented. The generation of the problem resulting from the etch residue of filling insulating film 11 in region B is suppressed. As a result, the reliability and the yield of a semiconductor device improve.

In this embodiment, the semiconductor device with which two kinds of insulating films from which thickness differs consist of thick gate oxide films and thin gate oxide films was explained. However, in the semiconductor device of the present invention, two kinds of insulating films from which thickness differs may be not only a gate oxide film but tunnel oxide films used by a flash memory.

By using the manufacturing method of the semiconductor device of this above-mentioned embodiment, also when three or more kinds of insulating films, a thick insulating film, the insulating film of the thickness of the degree of middle, a thin insulating film, etc., are formed on a semiconductor substrate, the upper surface of three or more kinds of insulating films may be mostly positioned in the same plane. The effect that is the same as that of the manufacturing method of the semiconductor device of this embodiment is acquired by this.

### Embodiment 2

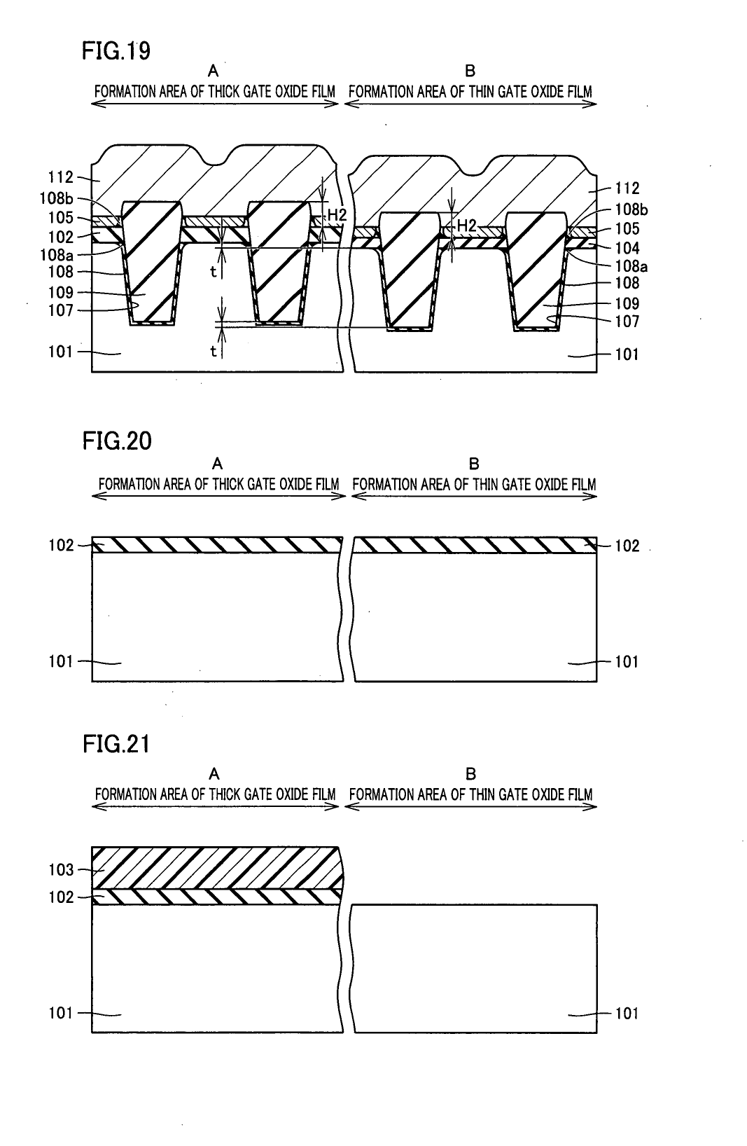

First, the semiconductor device of an embodiment of the invention and its manufacturing method are explained using FIG. 19-FIG. 33. Also in the structure shown in FIG. 19, at least two kinds of insulating films from which thickness differs are formed on the active region of a semiconductor substrate. The active region which has at least two kinds of insulating films is separated by at least one element isolation insulating film.

The semiconductor device of this embodiment is provided with silicon substrate 101 as an example of a semiconductor substrate as shown in FIG. 19. On the main front surface of silicon substrate 101 in region A, thick gate oxide film 102 as an example of the first insulating film of the present invention is formed. On the other hand, on the main front surface of silicon substrate 101 in region B, thin gate oxide film 104 as an example of the second insulating film of the present invention is formed.

On each of thick gate oxide film 102 and thin gate oxide film 104, first polysilicon film 105 as an example of the first electric conduction film of the present invention is formed. Since they are simultaneously formed in the same step, first polysilicon film 105 formed in region A, and first polysilicon film 105 formed in region B have substantially same and fixed thickness (about ±10%) within the limits of the variation generated in the usual film formation technology.

In region A, first polysilicon film 105 and thick gate oxide film 102 are penetrated, and trench 107 which reaches the position of the predetermined depth from the main front surface of silicon substrate 101 is formed. In region B, first polysilicon film 105 and thin gate oxide film 104 are penetrated, and trench 107 which reaches the position of the predetermined depth from the main front surface of silicon substrate 101 is formed. Trench 107 in region A is equivalent to the first trench of the present invention, and trench 107 in region B is equivalent to the second trench of the present invention.

In this embodiment, inner wall silicon oxide film 108 as an example of the inner wall insulating film of the present invention is formed along the front surface of trench 107. Inner wall silicon oxide film 108 has bird's beak parts 108a and 108b. Bird's beak parts 108a and 108b are prolonged along the direction parallel to the main front surface of silicon substrate 1, respectively.

In the recess formed of inner wall silicon oxide film 108, insulating films, such as a CVD oxide film, are embedded and filling insulating film (separation insulating film) 109 as an example of the element isolation insulating part of the present invention is formed. Filling insulating film 109 is prolonged from the upper surface of first polysilicon film 105 to the position of predetermined height. Along the form of the upper surface of first polysilicon film 105, and the front surface of the top end of filling insulating film 109, second polysilicon film 112 as an example of the second electric conduction film of the present invention is formed so that the upper surface of first polysilicon film 105 and the front surface of filling insulating film 109 may be covered.

In this embodiment, the gate insulating film (or tunnel insulating film) which has two kinds of thickness is formed on the active region located between filling insulating films 109. On the gate insulating film, first polysilicon film 105 and second polysilicon film 112 are formed in the shape of lamination.

According to the semiconductor device of this embodiment, the amount which removes filling insulating film 109 is controlled for every regions A and B before the step which removes silicon nitride film 106. Thereby, the height of the upper surface of filling insulating film 109 in region A differs from the height of the upper surface of filling insulating film 109 in region B. As a result, distance H2 from the upper surface of thick gate oxide film 102 to the upper surface of filling insulating film 109 in region A and distance H2 from the upper surface of thin gate oxide film 104 to the upper surface of filling insulating film 109 in region B are the same substantially. Therefore, fear of disconnection and a short circuit of second polysilicon 112, and a generation of the focal drift by subsequent steps becomes small like Embodiment 1.

When the difference of distance H2 from the upper surface of thick gate oxide film 102 to the upper surface of filling insulating film 109 in region A and distance H2 from the upper surface of thin gate oxide film 104 to the upper surface of filling insulating film 109 in region B is smaller than the difference of the distance of the upper surface of thick gate oxide film 102, and the upper surface of thin gate oxide film 104, as compared with the corresponding structure of the above-mentioned comparative example, fear of a generation of disconnection and a short circuit of second polysilicon film 112, and a focal drift in region B becomes small.

Next, the manufacturing method of the semiconductor device of this embodiment is explained using FIG. 20-FIG. 33. In the manufacturing method of the semiconductor device of this embodiment, first, as shown in FIG. 20, thick gate oxide film 102 as an example of the first insulating film of the present invention is formed by thermal oxidation on silicon substrate 101 of an example of the semiconductor substrate of the present invention in regions A and B. Next, resist layer 103 is formed on thick gate oxide film 102 in region A. Then, as shown in FIG. 21, etching is performed by using resist layer 103 as a mask. Thereby, thick gate oxide film 102 in region B is removed. As a result, thick gate oxide film 102 remains to region A.

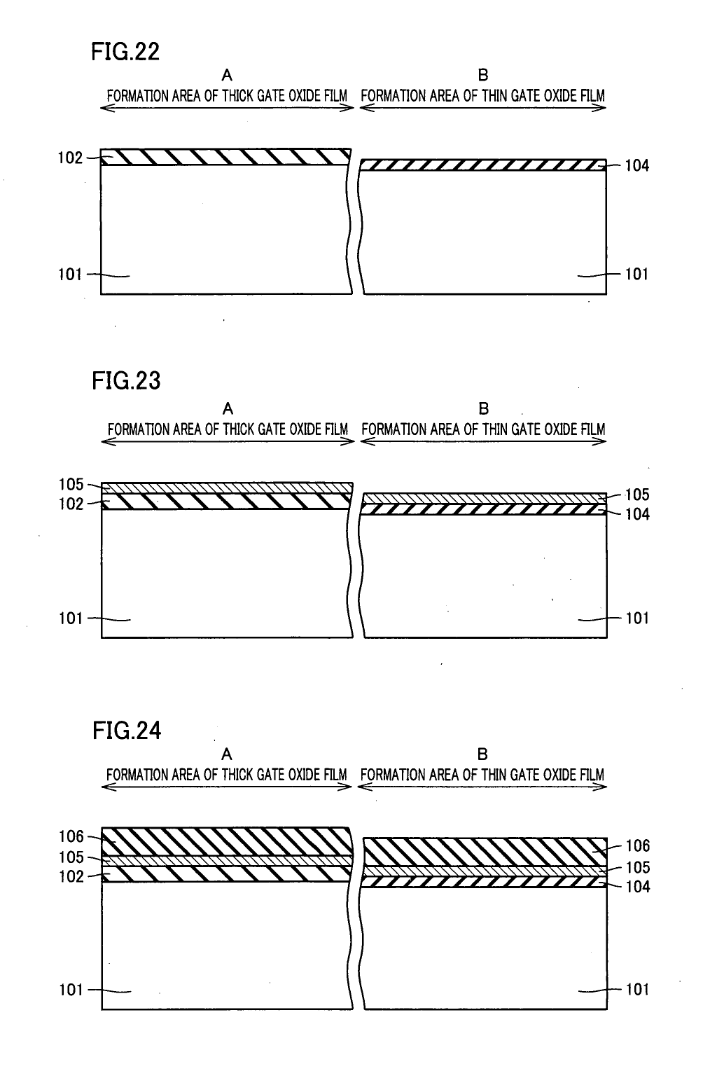

Next, as shown in FIG. 22, thin gate oxide film 104 as an example of the second insulating film of the present invention is formed by thermal oxidation on silicon substrate 101. At this time, the position of the upper surface of thin gate oxide film 104 is lower than the position of the upper surface of thick gate oxide film 102. Then, in regions A and B, as shown in FIG. 23, first polysilicon film 105 which has fixed thickness substantially is formed on thick gate oxide film 102 and thin gate oxide film 104. Next, as shown in FIG. 24, silicon nitride film 106 which has fixed thickness substantially is formed on first polysilicon film 105. Silicon nitride film 106 functions as a stopper film in the CMP process and etching step which are mentioned later.

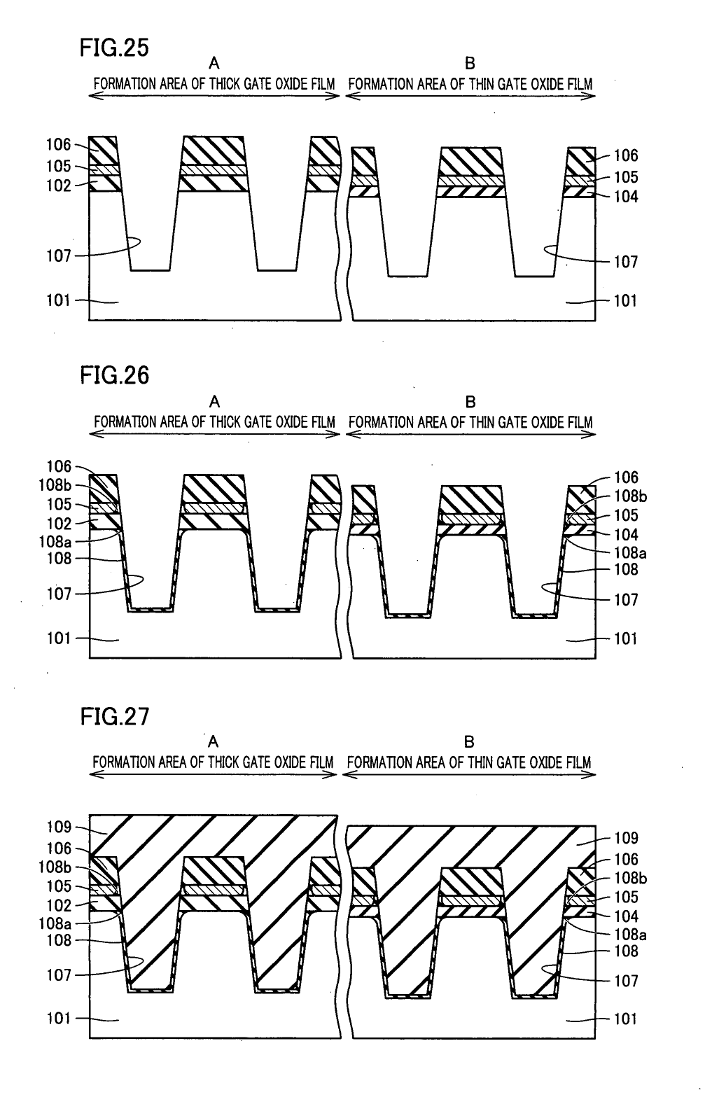

Next, as shown in FIG. 25, etching is performed using one mask. Thereby, in region A, silicon nitride film 106, first polysilicon film 105, thick gate oxide film 102, and the portion of the depth predetermined from a main front surface of silicon substrate 101 are removed. Thereby, trench 107 corresponding to the first trench of the present invention is formed in region A. Simultaneously, in region B, silicon nitride film 106, first polysilicon film 105, thin gate oxide film 104, and the portion of the depth predetermined from a main front surface of silicon substrate 101 are removed. Thereby, trench 107 corresponding to the first trench of the present invention is formed in region B.

Next, thermal oxidation of the inner surface of trench 107 is done. Thereby, as shown in FIG. 26, inner wall silicon oxide film 108 as an example of the inner wall insulating film of the present invention is formed. At this time, bird's beak part 108a is formed in the position where the main front surface of silicon substrate 101 and trench 107 cross. Bird's beak part 108b is formed in first polysilicon film 105.

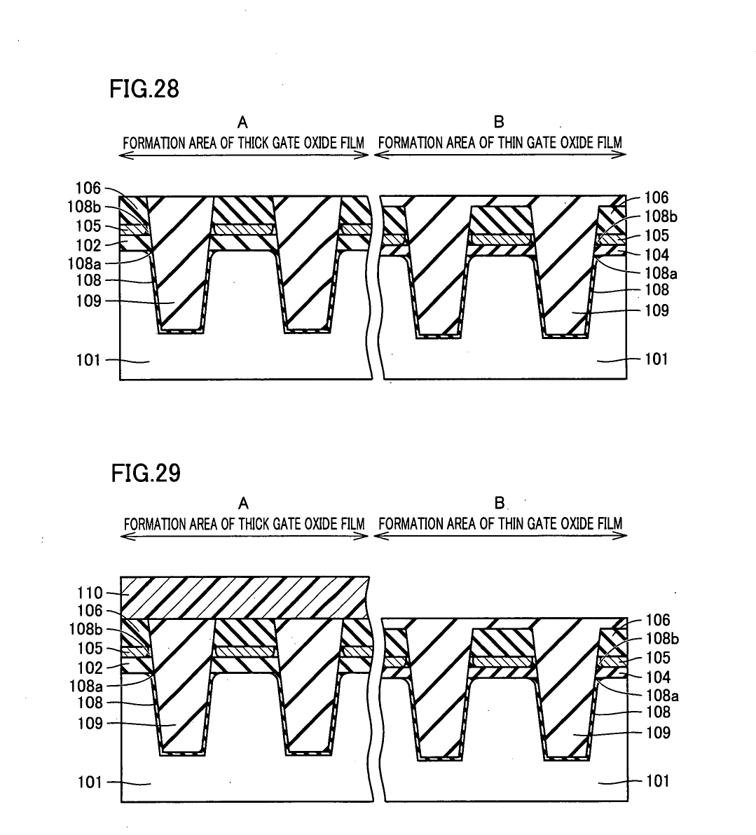

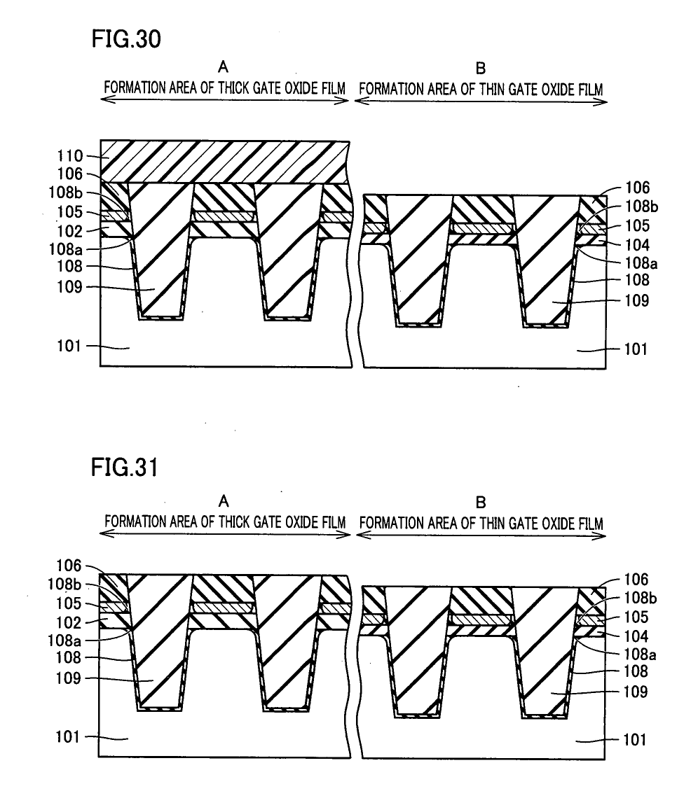

Then, as shown in FIG. 27, while filling insulating film 109 is filled up in trench 107 by CVD (Chemical Vapor Deposition), it is formed so that silicon nitride film 106 may be covered. Then, as shown in FIG. 28, flattening of the filling insulating film 109 is done so that the upper surface of silicon nitride film 106 in region A may be exposed with an etch back or chemical mechanical polishing. At this time, the height of the upper surface of filling insulating film 109 and the height of the upper surface of silicon nitride film 106 become the same substantially in region A. On the other hand, in region B, filling insulating film 109 remains on silicon nitride film 106. Therefore, as shown in FIG. 29, resist layer 110 is formed in region A, and filling insulating film 109 on silicon nitride film 106 is etched by using resist layer 110 as a mask. Thereby, filling insulating film 109 in region B is etched, without etching filling insulating film 109 in region A. As a result, as shown in FIG. 30, while the state where the upper surface of filling insulating film 109 and the upper surface of silicon nitride film 106 are positioned in the same plane in region A is maintained, the upper surface of filling insulating film 109 and the upper surface of silicon nitride film 106 are positioned in the same plane in region B. Then, as shown in FIG. 31, resist layer 110 is removed.

When the thickness of first polysilicon film 105 is 50 nm or less, even if the impurity is not introduced into first polysilicon film 105, section form will change from the form of the length of the lower side>length of the upper side to the form of the length of the upper side≧length of the lower side easily. This is because the oxidation seed (oxidizer) which oxidizes first polysilicon film 7 in a horizontal direction tends to diffuse the inside of a gate oxide film. When the thickness of first polysilicon film 105 is 20 nm±10 nm, i.e., 30 nm from 10 nm, it is more preferred.

When first polysilicon film 105 is a laminated structure which becomes high as impurity concentration goes to a lower part, it will change from the state of the length of the lower side>length of the upper side to the state of the length of the upper side≧length of the lower side easily. As a result, when first polysilicon film 105 is etched, it becomes difficult to generate an etch residue. First polysilicon film 105 changes from the state of the length of the lower side>length of the upper side to the state of the length of the upper side≧length of the lower side easily, even if an upside part consists of non doped polysilicon and the lower part consists of doped polysilicon.

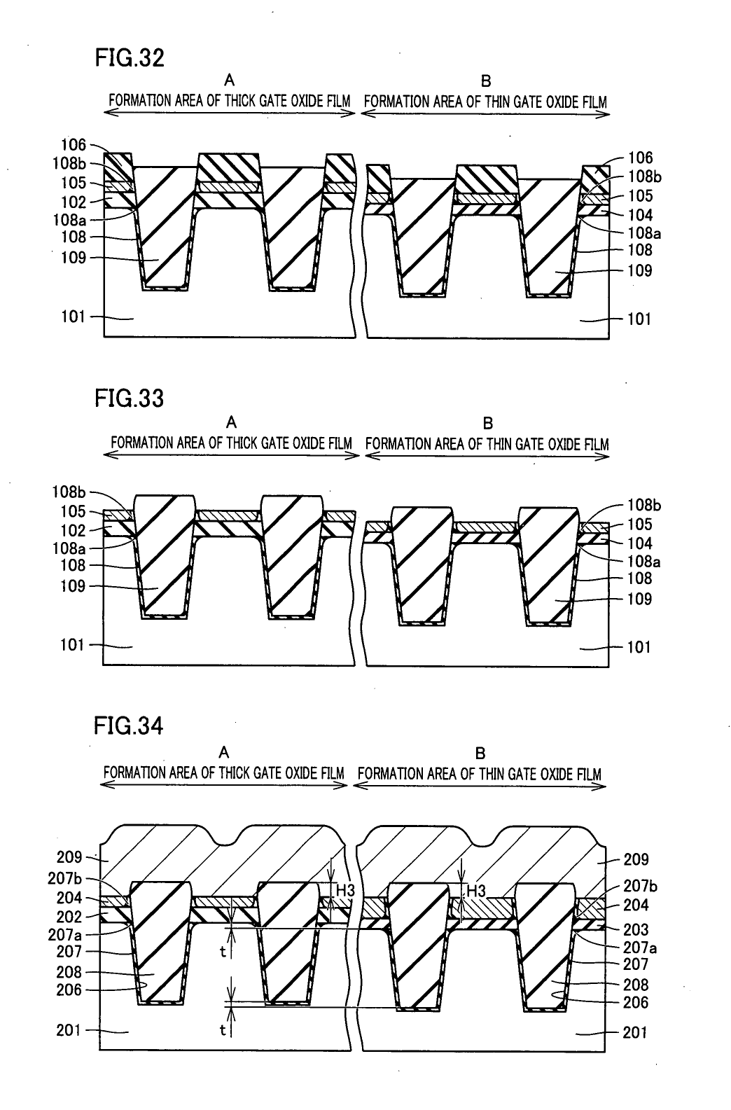

Then, as shown in FIG. 32, in order to adjust the height position of the upper surface of filling insulating film 109, filling insulating film 109 is etched by a plasma etch back or fluoric acid by using silicon nitride film 106 as an etching stopper film. At this time, filling insulating film 109 does not remain on silicon nitride film 106 in any of regions A and B. Therefore, the problem that the residue of filling insulating film 109 remains on silicon nitride film 106 is solved.

Next, as shown in FIG. 33, silicon nitride film 106 is removed by heat phosphoric acid. At this time, the width of the top end of filling insulating film 109 is narrowed. Then, as shown in FIG. 19, in each of regions A and B, along the form of the upper surface of first polysilicon film 105, and the front surface of the top end of filling insulating film 109, second polysilicon film 112 is formed so that first polysilicon film 105 and filling insulating film 109 may be covered. Next, first polysilicon 105 and second polysilicon film 112 are removed partially because of patterning. As a result, the forming step of SA-STI is completed.

Also in the manufacturing method of the semiconductor device of this embodiment, an electrically conductive impurity, for example, phosphorus (P), is introduced into second polysilicon film 112 like the manufacturing method of the semiconductor device of Embodiment 1. The doped amorphous silicon by which phosphorus (P) was doped in polysilicon (in-situ) may be formed instead of second polysilicon film 112. After a non-doped amorphous silicon film or a polysilicon film is formed, phosphorus (P) may be doped by those films with ion implantation. As for the concentration of phosphorus (P), in this embodiment, it is desirable that it is about 1.0E²⁰ atms/cm³-1.0E²¹ atms/cm³.

According to the manufacturing method of the semiconductor device of this embodiment, distance H2 from the upper surface of thick gate oxide film 102 to the upper surface of filling insulating film 109 and distance H2 from the upper surface of thin gate oxide film 104 to the upper surface of filling insulating film 109 become the same substantially.

The semiconductor device two kinds of whose insulating films from which thickness differs of this embodiment are a thick gate oxide film and a thin gate oxide film was explained. However, two kinds of insulating films from which thickness differs of the semiconductor device of the present invention may be not only a gate oxide film but tunnel oxide films used by a flash memory. That is, thick gate oxide film 102 or thin gate oxide film 104 may all function as a tunnel insulating film as a gate insulating film of a flash memory.

By using the manufacturing method of the semiconductor device of this above-mentioned embodiment, also when three or more kinds of insulating films, a thick insulating film, the insulating film of the thickness of the degree of middle, a thin insulating film, etc., are formed on a semiconductor substrate, distance from each upper surface of three or more kinds of insulating films to the corresponding upper surface of a filling insulating film may be substantially made the same. The effect that is the same as that of the manufacturing method of the semiconductor device of this embodiment is acquired by it.

As mentioned above, in the manufacturing method of the semiconductor device of this embodiment, the amount of removal of each filling insulating film 109 of regions A and B is controlled before the step which removes silicon nitride film 106. A difference is formed by it between the height of the upper surface of filling insulating film 109 in region A, and the height of the upper surface of filling insulating film 109 in region B. Thereby, distance H2 from the upper surface of thick gate oxide film 102 to the upper surface of filling insulating film 109 in region A and distance H2 from the upper surface of thin gate oxide film 4 to the upper surface of filling insulating film 109 of region B become the same substantially. For this reason, the generation of the residue of filling insulating film 109, the residue of silicon nitride film 106, and the residue of first polysilicon film 105 in region B can be suppressed. As a result, it becomes possible to improve the reliability and the yield of a semiconductor device.

### Embodiment 3

First, the semiconductor device of an embodiment of the invention and its manufacturing method are explained using FIG. 34-FIG. 47.

FIG. 34 is a drawing showing the structure of the semiconductor device of Embodiment 1. Also in the structure shown in FIG. 34, at least two kinds of insulating films from which thickness differs are formed on the active region of a semiconductor substrate. The active region which has at least two kinds of insulating films is separated by at least one element isolation insulating film. Hereafter, the structure of the semiconductor device of this embodiment is explained concretely.

As shown in FIG. 34, the semiconductor device of this embodiment is provided with silicon substrate 201 as an example of the semiconductor substrate of the present invention. On the main front surface of silicon substrate 201 in region A, thick gate oxide film 202 as an example of the first insulating film of the present invention is formed. On the other hand, on the main front surface of silicon substrate 201 in region B, thin gate oxide film 203 as an example of the second insulating film of the present invention is formed. On each of thick gate oxide film 202 and thin gate oxide film 203, first polysilicon film 204 as a first electric conduction film of the present invention is formed. The upper surface of first polysilicon film 204 formed in region A and the upper surface of first polysilicon film 204 formed in region B are substantially positioned in the same height.

In region A, first polysilicon film 204 and thick gate oxide film 202 are penetrated, and trench 206 which reaches the position of the predetermined depth from the main front surface of silicon substrate 201 is formed. Trench 206 in region A is equivalent to the first trench of the present invention. In region B, first polysilicon film 204 and thin gate oxide film 203 are penetrated, and trench 206 which reaches the position of the predetermined depth from the main front surface of silicon substrate 201 is formed. Trench 206 in region B is equivalent to the second trench of the present invention.

In this embodiment, inner wall silicon oxide film 207 as an example of the inner wall insulating film of the present invention is formed along the front surface of trench 206. In the recess formed of inner wall silicon oxide film 207, insulating films, such as a CVD oxide film, are embedded and filling insulating film (separation insulating film) 208 as an example of the element isolation insulating part of the present invention is formed. Filling insulating film 208 is prolonged from the upper surface of first polysilicon film 204 to the position of predetermined height. Along the form of the upper surface of first polysilicon film 204, and the front surface of the top end of filling insulating film 208, second polysilicon film 209 as an example of the first electric conduction film of the present invention is formed so that the upper surface of first polysilicon film 204 and the top end of filling insulating film 208 may be covered.

According to the semiconductor device of this embodiment, flattening of the first polysilicon film 204 is done after the step which forms first polysilicon film 204. Thereby, the height position of the upper surface of first polysilicon film 204 in region A and the height position of the upper surface of first polysilicon film 204 in region B are the same substantially within the limits of the variation generated in the flattening step by usual CMP. Therefore, the thickness of first polysilicon film 204 in region A is smaller than the thickness of first polysilicon film 204 in region B. Therefore, the resistance of the gate electrode layer which consists of first polysilicon film 204 and second polysilicon film 209 in region B is smaller than the resistance of the gate electrode layer which consists of first polysilicon film 204 and second polysilicon film 209 in region A. Therefore, the answering delay of the gate electrode layer in region B is improved. Since the thin transistor which has a thin gate oxide film has a gate smaller than the thick transistor which has a thick gate oxide film, this is usually especially effective. When doing the over-etching of the first polysilicon film 204, the shaving of thin gate oxide film 203 in region B is smaller than the shaving of thick gate oxide film 202 in region A. Therefore, the grade of damage to thin gate oxide film 203 is small.

Distance H3 from the upper surface of first polysilicon film 204 to the upper surface of filling insulating film 208 in region A and distance H3 from the upper surface of first polysilicon film 204 to the upper surface of filling insulating film 208 in region B are the same substantially Therefore, fear of a generation of disconnection and a short circuit of second polysilicon film 209, and the focal drift by subsequent steps becomes small like Embodiment 1.

When the difference of distance H3 from the upper surface of first polysilicon film 204 to the upper surface of filling insulating film 208 in region A and distance H3 from the upper surface of first polysilicon film 204 to the upper surface of filling insulating film 208 in region B is smaller than the difference of the distance of the upper surface of thick gate oxide film 202, and the upper surface of thin gate oxide film 203, as compared with the corresponding structure of the above-mentioned comparative example, disconnection and a short circuit of second polysilicon film 209 in region B, and fear of a generation of a focal drift become small.

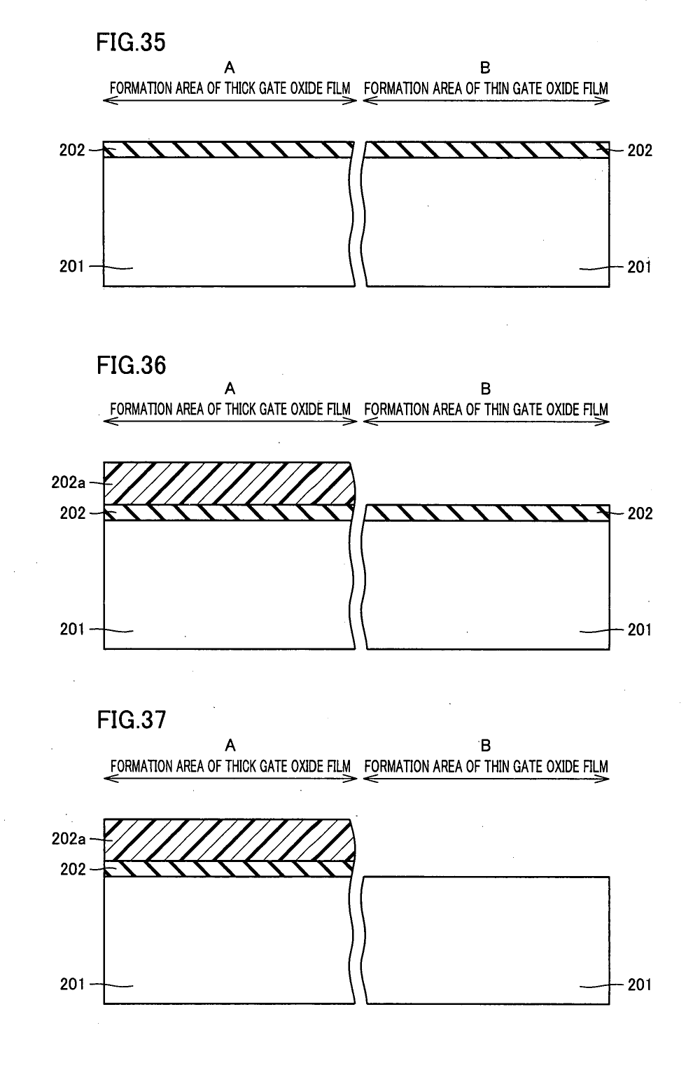

Next, the manufacturing method of the semiconductor device of this embodiment is explained, referring to FIG. 35-FIG. 47.

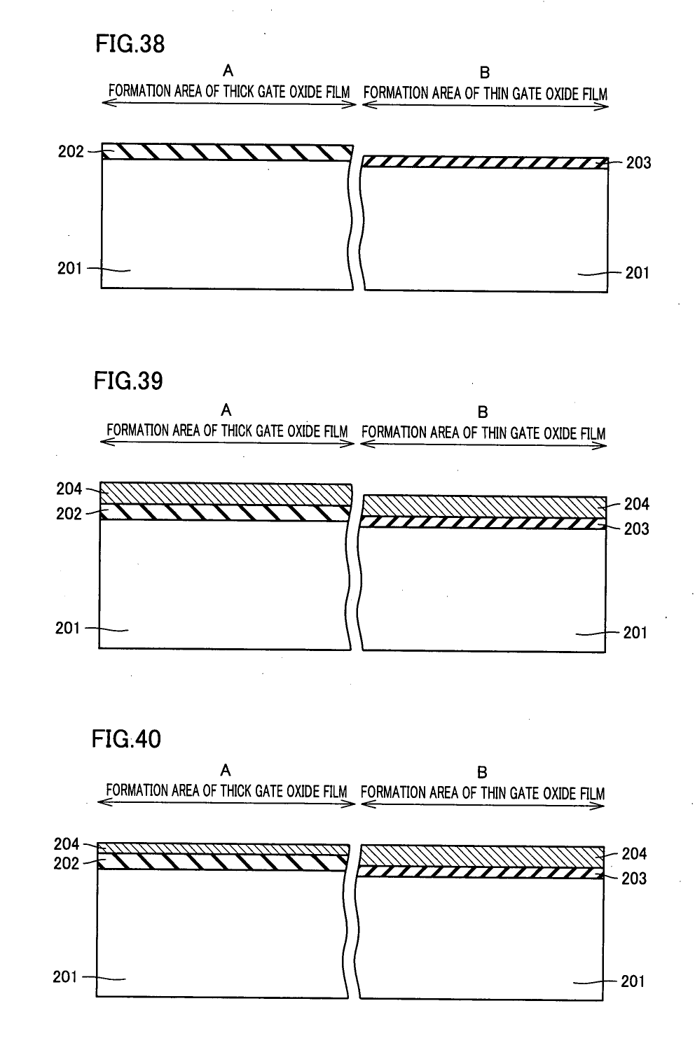

As shown in FIG. 35, thick gate oxide film 202 as an example of a first insulating film is first formed on silicon substrate 201 as an example of the semiconductor substrate of the present invention. Next, as shown in FIG. 36, resist layer 202a is formed on thick gate oxide film 202 in region A. Then, as shown in FIG. 37, thick gate oxide film 202 in region B is removed by etching. Thereby, thick gate oxide film 202 remains only in region A. The main front surface of silicon substrate 1 in region B is exposed. Next, as shown in FIG. 38, thin gate oxide film 203 as an example of the second insulating film of the present invention is formed on silicon substrate 201. At this time, the upper surface of thin gate oxide film 203 is positioned lower than the upper surface of thick gate oxide film 202.

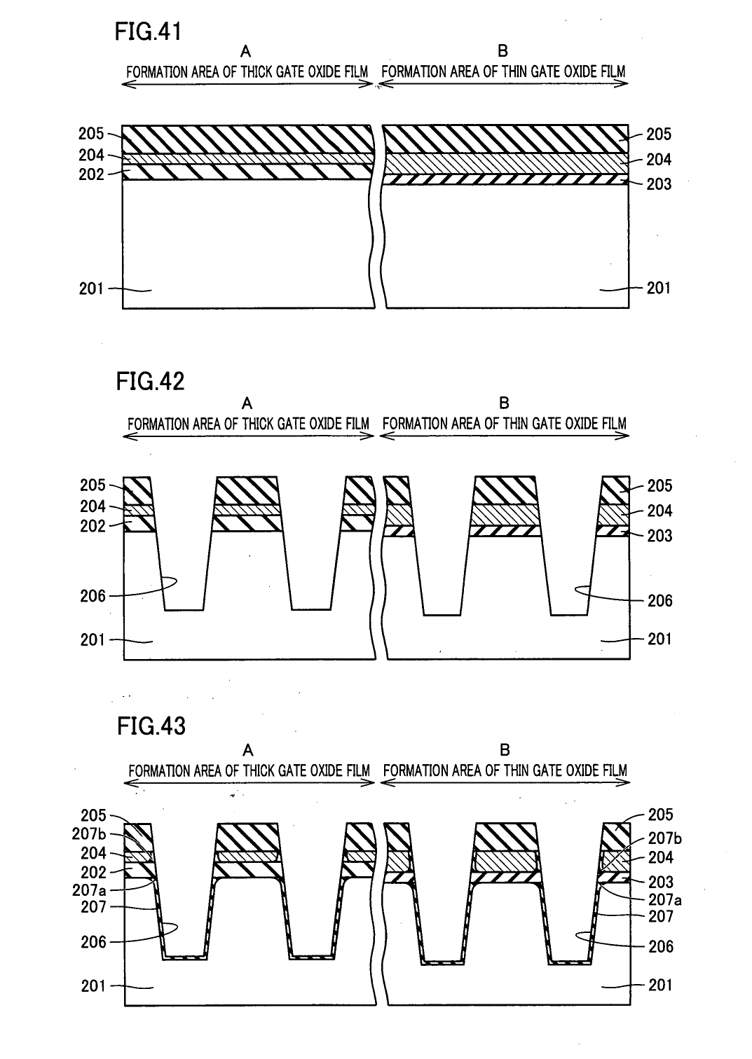

Next, as shown in FIG. 39, first polysilicon film 204 as an example of the first conductive layer of the present invention is formed on thick gate oxide film 202. Then, flattening of the first polysilicon film 204 is done by an etch back or chemical mechanical polishing. Thereby, as shown in FIG. 40, the height of the upper surface of first polysilicon film 204 in region A and the height of the upper surface of first polysilicon film 204 of region B become the same within the limits of the variation generated in the flattening step by usual CMP. Then, as shown in FIG. 41, silicon nitride film 205 as an example of a stopper film is formed on first polysilicon film 204 by which flattening was done.

Next, as shown in FIG. 42, etching is performed using one mask. Thereby, in region A, trench 206 which penetrates silicon nitride film 205, first polysilicon film 204, and thick gate oxide film 202, and results in the predetermined depth from the main front surface of silicon substrate 201 is formed. Trench.206 in region A is equivalent to the first trench of the present invention. In region B, silicon nitride film 205, first polysilicon film 204, and thin gate oxide film 203 are penetrated, and trench 206 which results in the predetermined depth from the main front surface of silicon substrate 201 is formed. Trench 206 in region B is equivalent to the second trench of the present invention.

Then, inner wall silicon oxide film 207 as an example of the inner wall insulating film of the present invention is formed in the front surface of trench 206 by thermal oxidation. At this time, as shown in FIG. 43, bird's beak part 207a is formed in the upper end of inner wall silicon oxide film 207. Bird's beak part 207b prolonged inside from the side surface of first polysilicon film 204 is formed.

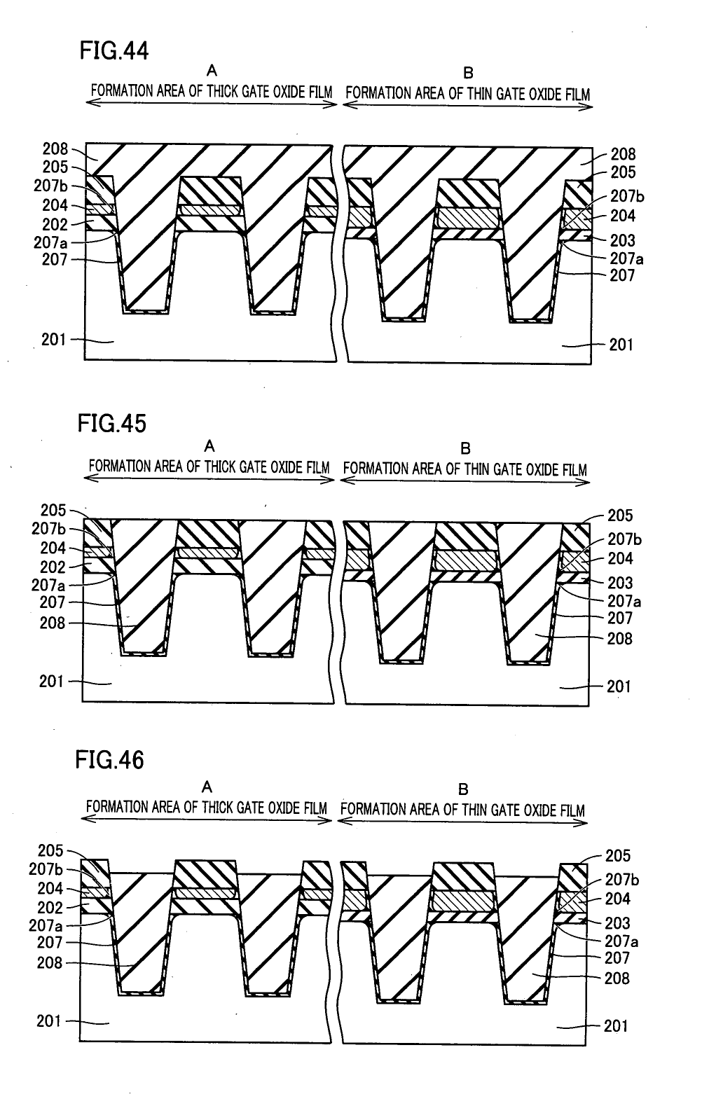

Next, as shown in FIG. 44, while trench 206 is embedded, filling insulating film 208 which covers silicon nitride film 205 is formed by CVD (Chemical Vapor Deposition). Then, flattening of the filling insulating film 208 is done by an etch back or chemical mechanical polishing until the front surface of silicon nitride film 205 is exposed, as shown in FIG. 45.

At this time, the height of the upper surface of silicon nitride film 205 in region A and the height of the upper surface of silicon nitride film 205 in region B are substantially the same. Therefore, a possibility in region B that the residue of etching of silicon nitride film 205 may occur is reduced.

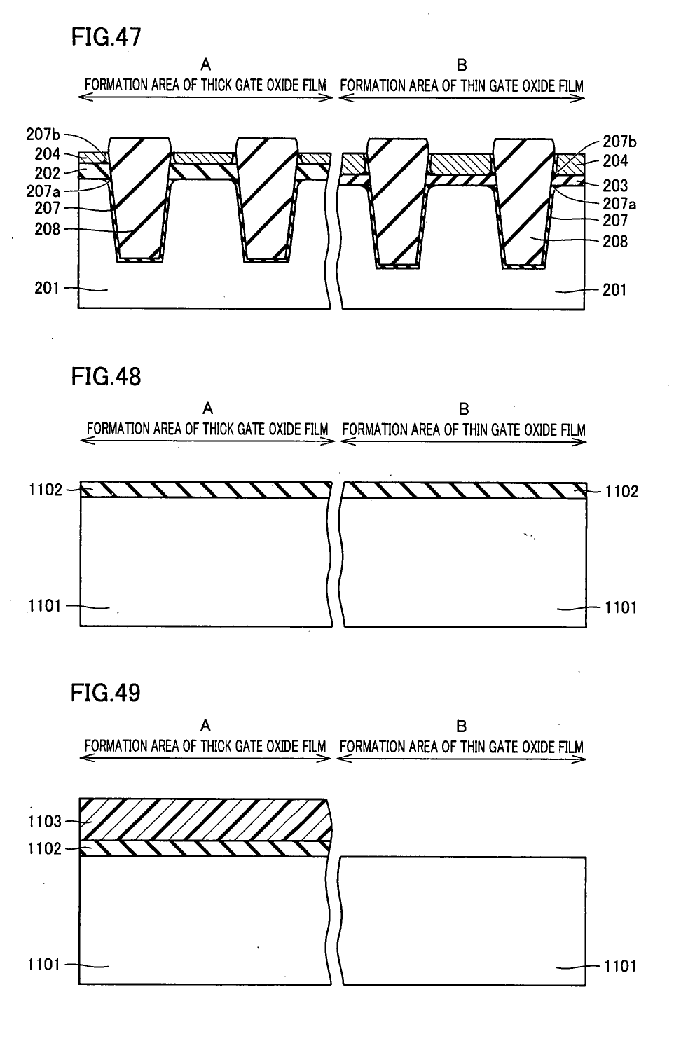

Next, as shown in FIG. 46, a plasma etch back is performed or etching using fluoric acid is performed so that the height position of the upper surface of filling insulating film 208 may be adjusted by using silicon nitride film 205 as a stopper film. Then, as shown in FIG. 47, silicon nitride film 205 is removed by heat phosphoric acid. At this time, the width of the top end of filling insulating film 208 is narrowed. Next, along the upper surface of first polysilicon film 204, and the surface form of a top end of filling insulating film 208, second polysilicon film 209 is formed so that first polysilicon film 204 and filling insulating film 208 may be covered. Then, the first and second polysilicon film 209 are removed partially because of patterning. Thereby, the forming step of SA-STI is completed.

In the manufacturing method of the semiconductor device of this embodiment, an electrically conductive impurity, for example, phosphorus (P), is introduced into second polysilicon film 209. The doped amorphous silicon by which phosphorus (P) was doped in polysilicon (in-situ) may be formed instead of second polysilicon film 209. After a non-doped amorphous silicon film or a polysilicon film is formed, phosphorus (P) may be doped in those films with ion implantation. As for the concentration of phosphorus (P), in this embodiment, it is desirable that it is about 1.0E²⁰ atms/cm³ -1.0E²¹ atms/cm³.

According to the manufacturing method of the semiconductor device of this embodiment, the height from the upper surface of first polysilicon film 204 to the upper surface of filling insulating film 208 in region A and the height from the upper surface of first polysilicon film 204 to the upper surface of filling insulating film 208 in region B become the same substantially.

Although the semiconductor device two kinds of whose insulating films from which thickness differs of this embodiment are a thick gate oxide film and a thin gate oxide film was explained, two kinds of insulating films from which thickness differs of the semiconductor device of the present invention may be not only a gate oxide film but tunnel oxide films used by a flash memory. That is, thick gate oxide film 202 or thin gate oxide film 203 may all function as a tunnel insulating film as a gate insulating film of a flash memory

By using the manufacturing method of the semiconductor device of this above-mentioned embodiment, also when three or more kinds of insulating films, a thick insulating film, the insulating film of the thickness of the degree of middle, a thin insulating film, etc., are formed on a semiconductor substrate, the upper surface of three or more kinds of insulating films may be mostly positioned in the same plane. Thereby, the effect that is the same as that of the manufacturing method of the semiconductor device of this embodiment is acquired.

According to the manufacturing method of the semiconductor device of this embodiment, flattening of the first polysilicon film 204 is done after the step in which first polysilicon film 204 is formed. Therefore, distance H3 from the upper surface of first polysilicon film 204 to the upper surface of filling insulating film 208 in region A and distance H3 from the upper surface of first polysilicon film 204 to the upper surface of filling insulating film 208 in region B become the same substantially. As a result, the generation of the residue of filling insulating film 208, the residue of silicon nitride film 205, and the residue of first polysilicon film 204 can be prevented. Therefore, the characteristics and the yield of a semiconductor device can be improved.

It should be thought that the embodiment disclosed this time is exemplification at all points, and not restrictive. The range of the present invention is shown by not the above-mentioned explanation but the claim, and it is meant that a meaning and all the change in within the limits as equal as a claim are included.

What is claimed is:

1. A semiconductor device, comprising:
a semiconductor substrate;
a first insulating film formed over a main front surface in a first region of the semiconductor substrate;
a second insulating film thinner than the first insulating film formed over a main front surface in a second region of the semiconductor substrate;
a first electric conduction film formed over the first and the second insulating film;
a first trench which penetrates the first electric conduction film and the first insulating film, and results in the first region from a main front surface of the semiconductor substrate to a position of a predetermined depth;
a first element isolation insulating part projected from an upper surface of the first electric conduction film while being embedded at the first trench;
a second trench which penetrates the first electric conduction film and the second insulating film, and results in the second region from a main front surface of the semiconductor substrate to a position of a predetermined depth;
a second element isolation insulating part projected from an upper surface of the first electric conduction film while being embedded at the second trench; and
a second electric conduction film formed along those form over a front surface of a top end of the first element isolation insulating part, an upper surface of the first electric conduction film, and a front surface of a top end of the second element isolation insulating part;
wherein
a thickness of the first electric conduction film is substantially constant in the first region and the second region;
a position of an under surface of the first insulating film is lower than a position of an under surface of the second insulating film; and
a difference of a position of an upper surface of the first insulating film and a position of an upper surface of the second insulating film is smaller than a difference of a thickness of the first insulating film, and a thickness of the second insulating film.

2. A semiconductor device according to claim 1, wherein
a height position of an upper surface of the first insulating film and a height position of an upper surface of the second insulating film are substantially the same.

3. A semiconductor device according to claim 2, wherein
a distance from an upper surface of the first insulating film to an upper surface of the first element isolation insulating part and a distance from an upper surface of the second insulating film to an upper surface of the second element isolation insulating part are substantially the same.

4. A semiconductor device according to claim 3, wherein
a position of a bottom of the first trench is lower than a position of a bottom of the second trench.

5. A semiconductor device, comprising:
a semiconductor substrate;
a first insulating film formed over a main front surface in a first region of the semiconductor substrate;
a second insulating film thinner than the first insulating film formed over a main front surface in a second region of the semiconductor substrate;
a first electric conduction film formed over the first and the second insulating film;
a first trench which penetrates the first electric conduction film and the first insulating film, and results in the first region from a main front surface of the semiconductor substrate to a position of a predetermined depth;
a first element isolation insulating part projected from an upper surface of the first electric conduction film while being embedded at the first trench;
a second trench which penetrates the first electric conduction film and the second insulating film, and results in the second region from a main front surface of the semiconductor substrate to a position of a predetermined depth;
a second element isolation insulating part projected from an upper surface of the first electric conduction film while being embedded at the second trench; and
a second electric conduction film formed along those form over a front surface of a top end of the first element isolation insulating part, an upper surface of the first electric conduction film, and a front surface of a top end of the second element isolation insulating part;
wherein
a difference of a distance from an upper surface of the first insulating film to an upper surface of a first element isolation insulating part and a distance from an upper surface of the second insulating film to an upper surface of the second element isolation insulating part is smaller than a difference of a distance between an upper surface of the first insulating film, and an upper surface of the second insulating film.

6. A semiconductor device according to claim 5, wherein
a distance from an upper surface of the first insulating film to an upper surface of the first element isolation insulating part and a distance from an upper surface of the second insulating film to an upper surface of the second element isolation insulating part are substantially the same.

7. A semiconductor device, comprising:
a semiconductor substrate;
a first insulating film formed over a main front surface in a first region of the semiconductor substrate;
a second insulating film thinner than the first insulating film formed over a main front surface in a second region of the semiconductor substrate;
a first electric conduction film formed over the first insulating film and the second insulating film;
a first trench which penetrates the first electric conduction film and the first insulating film, and results in the first region from a main front surface of the semiconductor substrate to a position of a predetermined depth;
a first element isolation insulating part projected from an upper surface of the first electric conduction film while being embedded at the first trench;
a second trench which penetrates the first electric conduction film and the second insulating film, and results in the second region from a main front surface of the semiconductor substrate to a position of a predetermined depth;
a second element isolation insulating part projected from an upper surface of the first electric conduction film while being embedded at the second trench; and
a second electric conduction film formed along those form over a front surface of a top end of the first element isolation insulating part, an upper surface of the first electric conduction film, and a front surface of a top end of the second element isolation insulating part;
wherein
a difference of a distance from an upper surface of the first electric conduction film to an upper surface of the first element isolation insulating part in the first region and a distance from an upper surface of the first electric conduction film to an upper surface of the second element isolation insulating part in the second region is smaller than a distance between an upper surface of the first insulating film, and an upper surface of the second insulating film.

8. A semiconductor device according to claim 7, wherein
a distance from an upper surface of the first electric conduction film to an upper surface of the first element isolation insulating part in the first region and a distance from an upper surface of the first electric conduction film to an upper surface of the second element isolation insulating part in the second region are substantially the same.

9. A semiconductor device according to claim 7, wherein
a height of an upper surface of the first conductive layer in the first region and a height of an upper surface of the first conductive layer in the second region are substantially the same.

10. A semiconductor device according to claim 7, wherein
a thickness of the first conductive layer in the second region is larger than a thickness of the first conductive layer in the first region.

11. A method of manufacturing a semiconductor device, comprising the steps of:
preparing a structure where a first insulating film is formed over a main front surface in a first region of a semiconductor substrate, and a second insulating film thinner than the first insulating film which has an under surface positioned over a main front surface in a second region of the semiconductor substrate more highly than an under surface of the first insulating film is formed;
forming a first electric conduction film whose thickness is substantially constant over the first insulating film and the second insulating film;
forming a stopper film over the first electric conduction film;
forming a second trench which penetrates the stopper film, the first electric conduction film, and the second insulating film, and is prolonged from a main front surface of the semiconductor substrate to a second position of a predetermined depth in the second region, while forming a first trench which penetrates the stopper film, the first electric conduction film, and the first insulating film, and is prolonged from a main front surface of the semiconductor substrate to a first position of a predetermined depth in the first region;
forming a third insulating film which covers the first electric conduction film while embedding each of the first trench and the second trench;
exposing an upper surface of the stopper film by Chemical Mechanical Polishing of the third insulating film;
etching a top end of the third insulating film in the first trench and the second trench by using the stopper film as a mask;
removing the stopper film; and
forming a second electric conduction film so that a form of a front surface of a top end of the third insulating film in the first region, an upper surface of the first electric conduction film, and a front surface of a top end of the third insulating film in the second region may be met.

12. A method of manufacturing a semiconductor device according to claim 11, wherein
in the step which prepares the structure, a level difference is formed in a main front surface of the semiconductor substrate so that a height position of an upper surface of the first insulating film and a height position of an upper surface of the second insulating film may become the same substantially,

13. A method of manufacturing a semiconductor device according to claim 11, the step of preparing the structure comprising the steps of:
forming a first oxidation treatment insulating film by oxidation treatment over the semiconductor substrate in each of the first region and the second region;
removing the first oxidation treatment insulating film in the first region;
changing the first oxidation treatment insulating film in the second region to a third oxidation treatment insulating film which has bigger thickness than it, while forming a second oxidation treatment insulating film over a main front surface of the semiconductor substrate in the first region by each oxidation treatment of the first region and the second region for a second time;
removing the second oxidation treatment insulating film;
changing the third oxidation treatment insulating film in the second region to a fifth oxidation treatment insulating film which has bigger thickness than it, while forming a fourth oxidation treatment insulating film over a main front surface of the semiconductor substrate in the first region by each oxidation treatment of the first region and the second region for a second time;
removing the fifth oxidation treatment insulating film; and
changing the fifth oxidation-treatment insulating film to the first insulating film in the first region, and forming the second insulating film in the second region by each oxidation treatment of the first region and the second region for a second time.

14. A method of manufacturing a semiconductor device according to claim 11, further comprising a step of:
forming an insulating film over a front surface of the semiconductor substrate which forms the first trench and the second trench, and the first electric conduction film by performing oxidation treatment in a state where the first trench and the second trench are exposed;
wherein a concentration of impurities of a lower part of the first electric conduction film is higher than a concentration of impurities of an upper part of the first electric conduction film.

15. A method of manufacturing a semiconductor device according to claim 14, wherein
the first electric conduction film has thickness of 50 nm or less.

16. A method of manufacturing a semiconductor device, comprising the steps of:
forming a first insulating film over a main front surface of a semiconductor substrate;
making a first insulating film in a first region of the first insulating films remain, and exposing the semiconductor substrate by removing a first insulating film in a second region;
forming a second insulating film thinner than the first insulating film over a main front surface of the semiconductor substrate in the second region;
forming a first electric conduction film whose thickness is substantially constant over the first insulating film and the second insulating film;
forming a stopper film over the first electric conduction film;
forming a second trench which penetrates the stopper film, the first electric conduction film, and the second insulating film, and is prolonged from a main front surface of the semiconductor substrate to a second position of a predetermined depth in the second region, while forming a first trench which penetrates the stopper film, the first electric conduction film, and the first insulating film, and is prolonged from a main front surface of the semiconductor substrate to a first position of a predetermined depth in the first region;
forming a third insulating film which covers the first electric conduction film while embedding the first trench and the second trench;
exposing an upper surface of the stopper film in the first region by Chemical Mechanical Polishing of the third insulating film;
removing the third insulating film in the second region positioned above an upper surface of the stopper film where the first region is masked;
etching the third insulating film in the first trench and the second trench by using the stopper film as a mask;
removing the stopper film; and
forming a second electric conduction film so that a form of a front surface of a top end of the third insulating film in the first region, an upper surface of the first electric conduction film, and a front surface of a top end of the third insulating film in the second region may be met.

17. A method of manufacturing a semiconductor device according to claim 16, further comprising a step of:
forming an insulating film over a front surface of a semiconductor substrate which forms the first trench and the second trench, and a first electric conduction film by performing oxidation treatment in a state where the first trench and the second trench are exposed;
wherein a concentration of impurities of a lower part of the first electric conduction film is higher than a concentration of impurities of an upper part of the first electric conduction film.

18. A method of manufacturing a semiconductor device according to claim 17, wherein
the first electric conduction film has thickness of 50 nm or less.

19. A method of manufacturing a semiconductor device, comprising the steps of:
forming a first insulating film over a main front surface of a semiconductor substrate;
making a first insulating film in a first region of the first insulating films remain, and exposing the semiconductor substrate in a second region by removing a first insulating film in the second region;
forming a second insulating film thinner than the first insulating film over a main front surface of the semiconductor substrate in the second region;
forming a first electric conduction film whose thickness is substantially constant over the first insulating film and the second insulating film;
doing Chemical Mechanical Polishing of the first electric conduction film in the first region;
forming a stopper film over the first electric conduction film;
forming a second trench which penetrates the stopper film, the first electric conduction film, and the second insulating film, and is prolonged from a main front surface of the semiconductor substrate to a second position of a predetermined depth in the second region, while forming a first trench which penetrates the stopper film, the first electric conduction film, and the first insulating film, and is prolonged from a main front surface of the semiconductor substrate to a first position of a predetermined depth in the first region;
forming a third insulating film which covers the first electric conduction film while embedding the first trench and the second trench;
exposing an upper surface of the stopper film by Chemical Mechanical Polishing of the third insulating film;
etching the third insulating film in the first trench and the second trench by using the stopper film as a mask;
removing the stopper film; and
forming a second electric conduction film so that a form of a front surface of a top end of the third insulating film in the first region, an upper surface of the first electric conduction film, and a front surface of a top end of the third insulating film in the second region may be met.

20. A method of manufacturing a semiconductor device according to claim 19, wherein
in the step of doing Chemical Mechanical Polishing of the first conductive layer, Chemical Mechanical Polishing of the first electric conduction film in the first region is done so that a height position of an upper surface of the first electric conduction film in the first region and a height position of an upper surface of the first electric conduction film in the second region may become the same substantially.

21. A method of manufacturing a semiconductor device according to claim 19, further comprising a step of:
forming an insulating film over a front surface of a semiconductor substrate which forms the first trench and the second trench, and a first electric conduction film by performing oxidation treatment in a state where the first trench and the second trench are exposed;
wherein a concentration of impurities of a lower part of the first electric conduction film is higher than a concentration of impurities of an upper part of the first electric conduction film.

22. A method of manufacturing a semiconductor device according to claim 21, wherein
the first electric conduction film has thickness of 50 nm or less.
